(19) United States
(12) Patent Application Publication
(10) Pub. No.: US 2024/0043012 A1
(43) Pub. Date: Feb. 8, 2024

(54) FRICTION-COEFFICIENT-COMPUTING DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: MITSUYASU ABE, Nisshin-shi (JP); KEISUKE KAWAI, Kariya-city (JP); SHIGERU KAMIO, Kariya-city (JP); HAIBO LIU, Kariya-city (JP)

(21) Appl. No.: 18/360,419

(22) Filed: Jul. 27, 2023

(30) Foreign Application Priority Data
Jul. 29, 2022 (JP) 2022-121748

(51) Int. Cl. B60W 40/068; G06F 30/15

(52) U.S. Cl. CPC B60W 40/068; G06F 30/15; B60W 2520/26; B60W 2552/00; B60W 2552/40

(57) ABSTRACT

A friction-coefficient-computing device includes: a computing unit that calculates a slip ratio and a friction coefficient; and a maximum-friction-estimating unit that calculates an estimated maximum value of the friction. The maximum-friction-estimating unit includes: a model calculator that calculates a tire model friction, which is a friction coefficient of a tire brush model; and a parameter-estimating unit that estimates values of parameters of a tire brush model expression. The parameter-estimating unit includes a parameter-restricting unit that eliminates values of the parameters that allow the tire brush model expression to be a linear function and a quadratic function, and obtains values of the parameters that allow an inclination of an inflection point of the tire brush model expression to approach zero.

### CROSS REFERENCE TO RELATED APPLICATION

This application is based on Japanese Patent Application No. 2022-121748 filed on Jul. 29, 2022, the disclosure of which is incorporated herein by reference.

### TECHNICAL FIELD

The present disclosure relates to a friction-coefficient-computing device.

### BACKGROUND ART

As a method for controlling a driving force of an electric car, an optimal slip ratio is estimated, at which a driving force generated in the tire is maximized, and the slip ratio is controlled based on the estimated optimal slip ratio.

### SUMMARY

According to an aspect of the present disclosure, a friction-coefficient-computing device estimates an estimated maximum friction value, which is an estimated maximum value of a friction coefficient between a tire and a road surface, using a tire brush model that simulates a physical phenomenon between the tire and the road surface, and on a basis of a detection signal transmitted from a detection unit that detects information relating to the tire when a vehicle travels on the road surface. The friction-coefficient-computing device includes: a computing unit that calculates a slip ratio between the tire and the road surface, and calculates a friction coefficient between the tire and the road surface on a basis of the detection signal; and a maximum-friction-estimating unit that calculates the estimated maximum friction value using the slip ratio and the friction coefficient calculated by the computing unit, and a tire brush model expression, which is a computation expression indicating a relationship between a slip ratio and a friction coefficient in the tire brush model, and is for calculating an estimated friction coefficient between the tire and the road surface in a case where the slip ratio between the tire and the road surface is in a minute region where the slip ratio is less than a slip ratio at which wheelspin of the tire starts. Assuming that the slip ratio calculated by the computing unit is a calculated slip ratio, and the friction coefficient calculated by the computing unit is a calculated friction coefficient, the tire brush model expression is a function relating to the slip ratio of the tire brush model, and includes a plurality of parameters that varies an inclination of the tire brush model expression. The maximum-friction-estimating unit includes: a model calculator that substitutes the calculated slip ratio into the tire brush model expression to calculate a tire model friction, which is a friction coefficient of the tire brush model, and a parameter-estimating unit that estimates values of the parameters so as to make smaller a difference between the calculated friction coefficient and the tire model friction. The parameter-estimating unit includes a parameter-restricting unit that eliminates values of the parameters that allow the tire brush model expression to be a linear function and a quadratic function, and obtains values of the parameters that allow an inclination of an inflection point of the tire brush model expression to approach zero.

### BRIEF DESCRIPTION OF THE DRAWINGS

FIG. 1 is a schematic configuration diagram of a control device according to a first embodiment.

FIG. 2 is a diagram illustrating a friction-slip-ratio characteristic showing a correlation between a friction coefficient and a slip ratio.

FIG. 3 is a diagram illustrating theoretical characteristics in which a tire brush model expression is represented by a graph of a friction coefficient and a slip ratio.

FIG. 4 is a diagram illustrating an example in which a theoretical characteristic deviates from a friction-slip-ratio characteristic.

FIG. 5 is a flowchart illustrating an example of control processing executed by a slip calculator according to the first embodiment.

FIG. 6 is a flowchart illustrating an example of control processing executed by a friction calculator according to the first embodiment.

FIG. 7 is a flowchart illustrating an example of control processing executed by a model calculator according to the first embodiment.

FIG. 8 is a flowchart illustrating an example of control processing executed by an error calculator according to the first embodiment.

FIG. 9 is a flowchart illustrating an example of control processing executed by a parameter-estimating unit according to the first embodiment.

FIG. 10 is a flowchart illustrating an example of control processing executed by a maximum value calculator according to the first embodiment.

FIG. 11 is a diagram for explaining a method in which the maximum value calculator according to the first embodiment calculates an estimated maximum friction value.

FIG. 12 is a schematic configuration diagram of a control device according to a second embodiment.

FIG. 13 is a flowchart illustrating an example of control processing executed by a calculation memory according to the second embodiment.

FIG. 14 is a diagram for explaining the calculation memory and a calculation determiner according to the second embodiment.

FIG. 15 is a flowchart illustrating an example of control processing executed by the calculation determiner according to the second embodiment.

FIG. 16 is a diagram illustrating temporal variations in a calculated slip ratio and a calculated friction coefficient.

FIG. 17 is a diagram illustrating a theoretical characteristic in a case where calculated friction coefficients include outliers.

FIG. 18 is a schematic configuration diagram of a control device according to a third embodiment.

FIG. 19 is a diagram for explaining a calculation memory according to the third embodiment.

FIG. 20 is a flowchart illustrating an example of control processing executed by the calculation memory according to the third embodiment.

FIG. 21 is a diagram illustrating a state where calculated slip ratios having relatively close values and calculated friction coefficients having relatively close values are repeatedly detected.

FIG. 22 is a diagram illustrating an example of a theoretical characteristic in a case where calculated slip ratios having relatively close values and calculated friction coefficients having relatively close values are repeatedly detected.

FIG. 23 is a diagram illustrating an example of a theoretical characteristic obtained with parameters estimated by a parameter-estimating unit according to the third embodiment.

FIG. 24 is a schematic configuration diagram of a control device according to a fourth embodiment.

FIG. 25 is a diagram for explaining a calculation memory according to the fourth embodiment.

FIG. 26 is a flowchart illustrating an example of control processing executed by the calculation memory according to the fourth embodiment.

FIG. 27 is a flowchart illustrating an example of control processing executed by a data-complementing unit according to the fourth embodiment.

FIG. 28 is a diagram illustrating temporal variations in a calculated slip ratio and a calculated friction coefficient in a case where the calculated slip ratio and the calculated friction coefficient are detected in stepwise shapes.

FIG. 29 is a diagram illustrating an example of a theoretical characteristic in a case where only a calculated slip ratio and a calculated friction coefficient detected in stepwise shapes are used.

FIG. 30 is a diagram illustrating an example of a theoretical characteristic obtained with parameters estimated by a parameter-estimating unit according to the fourth embodiment.

### DETAILED DESCRIPTION

As a method for controlling the driving force of an electric car, a driving-force-controlling method is conventionally known using which an optimal slip ratio at which a driving force generated in the tire is maximized is estimated, and on the basis of the estimated optimal slip ratio, slip ratio control is performed. In this driving-force-controlling method, the optimal slip ratio is calculated using a computation expression of a cubic function relating to a slip ratio obtained from a relational expression between a driving force generated in the tire and a slip ratio in a tire brush model.

For example, the optimal slip ratio during sudden acceleration of the vehicle is a slip ratio immediately before a start of wheelspin of the tire. To obtain the optimal slip ratio, the speed of the vehicle and the speed of the tire are controlled so that the vehicle can be controlled in such a manner that a driving force generated in the tire is maximized and wheelspin of the tire is prevented.

The slip ratio has a correlation with the friction coefficient of the road surface. The friction coefficient increases as the slip ratio increases, and becomes a maximum value immediately before a start of wheelspin of the tire at which the slip ratio is optimal. The friction coefficient is information relating to the state of the road surface necessary for stable traveling of the vehicle, and in particular, information of the maximum value of the friction coefficient is important. Therefore, for example, in a navigation system, the map information is linked with the information of the maximum value of the friction coefficient of the road surface, so that the information of the maximum value of the friction coefficient can be effectively used. The friction coefficient is a value obtained by dividing the driving force generated in the tire by the normal force.

Therefore, the inventor considered calculation of an estimated maximum value of the friction coefficient using a computation expression. In a case where an estimated maximum value of the friction coefficient is calculated using the computation expression, the estimated maximum value of the friction coefficient can be accurately calculated by obtaining the optimal slip ratio. However, in order to obtain the optimal slip ratio, it is necessary to rotate the tire until immediately before a start of the wheelspin. It is not easy to rotate the tire until immediately before a start of the wheelspin.

Therefore, the inventor considered calculating an estimated maximum value of the friction coefficient by calculating a slip ratio less than the optimal slip ratio, and substituting the calculated slip ratio into the computation expression. However, the intensive consideration by the inventor has revealed that it is difficult to accurately calculate, using this method, an estimated maximum value of the friction coefficient.

The present disclosure provides a friction-coefficient-computing device that can accurately calculate an estimated maximum value of a friction coefficient.

According to an aspect of the present disclosure, a friction-coefficient-computing device estimates an estimated maximum friction value, which is an estimated maximum value of a friction coefficient between a tire and a road surface, using a tire brush model that simulates a physical phenomenon between the tire and the road surface, and on a basis of a detection signal transmitted from a detection unit that detects information relating to the tire when a vehicle travels on the road surface. The friction-coefficient-computing device includes: a computing unit that calculates a slip ratio between the tire and the road surface, and calculates a friction coefficient between the tire and the road surface on a basis of the detection signal; and a maximum-friction-estimating unit that calculates the estimated maximum friction value using the slip ratio and the friction coefficient calculated by the computing unit, and a tire brush model expression, which is a computation expression indicating a relationship between a slip ratio and a friction coefficient in the tire brush model, and is for calculating an estimated friction coefficient between the tire and the road surface in a case where the slip ratio between the tire and the road surface is in a minute region where the slip ratio is less than a slip ratio at which wheelspin of the tire starts. Assuming that the slip ratio calculated by the computing unit is a calculated slip ratio, and the friction coefficient calculated by the computing unit is a calculated friction coefficient, the tire brush model expression is a function relating to the slip ratio of the tire brush model, and includes a plurality of parameters that varies an inclination of the tire brush model expression. The maximum-friction-estimating unit includes: a model calculator that substitutes the calculated slip ratio into the tire brush model expression to calculate a tire model friction, which is a friction coefficient of the tire brush model, and a parameter-estimating unit that estimates values of the parameters so as to make smaller a difference between the calculated friction coefficient and the tire model friction. The parameter-estimating unit includes a parameter-restricting unit that eliminates values of the parameters that allow the tire brush model expression to be a linear function and a quadratic function, and obtains values of the parameters that allow an inclination of an inflection point of the tire brush model expression to approach zero.

In a case of the minute region where the slip ratio is less than the slip ratio at which wheelspin of the tire starts, the friction coefficient increases substantially in proportion to the slip ratio. Therefore, in a case where the tire brush model expression is approximated so that the friction coefficient increases substantially in proportion to the slip ratio, the parameters of the tire brush model expression include candidates that allow the tire brush model expression to be a linear function and a quadratic function.

However, according to intensive consideration by the inventor, in a case where the tire brush model expression is expressed by a linear function and a quadratic function, an estimated maximum friction value cannot be accurately calculated from the tire brush model expression.

According to intensive consideration by the inventor, the friction coefficient has a portion where when the slip ratio is a substantially maximum slip ratio, a ratio of a variation in the friction coefficient to an increase in the slip ratio is zero. Therefore, in a case where the tire brush model expression is approximated so that the friction coefficient has a portion where a ratio of a variation in the friction coefficient to an increase in the slip ratio is zero, the tire brush model expression has a portion where the inclination of the inflection point approaches zero.

As described above, according to the present disclosure, when the parameters of the tire brush model expression for calculating the friction coefficient in a case where the slip ratio is in the minute region are estimated, it is possible to exclude, from candidates for values of the parameters, candidates from which an estimated maximum friction value cannot be accurately calculated. Therefore, even in a case where the computing unit can calculate only values of the calculated slip ratio in the minute region, an estimated maximum friction value can be accurately calculated on the basis of estimated values of the parameters.

Embodiments of the present disclosure will be described hereafter referring to drawings. In the embodiments, a part that corresponds to a matter described in a preceding embodiment may be assigned with the same reference numeral, and redundant explanation for the part may be omitted. When only a part of a configuration is described in an embodiment, another preceding embodiment may be applied to the other parts of the configuration. The parts may be combined even if it is not explicitly described that the parts can be combined. The embodiments may be partially combined even if it is not explicitly described that the embodiments can be combined, provided there is no harm in the combination.

### First Embodiment

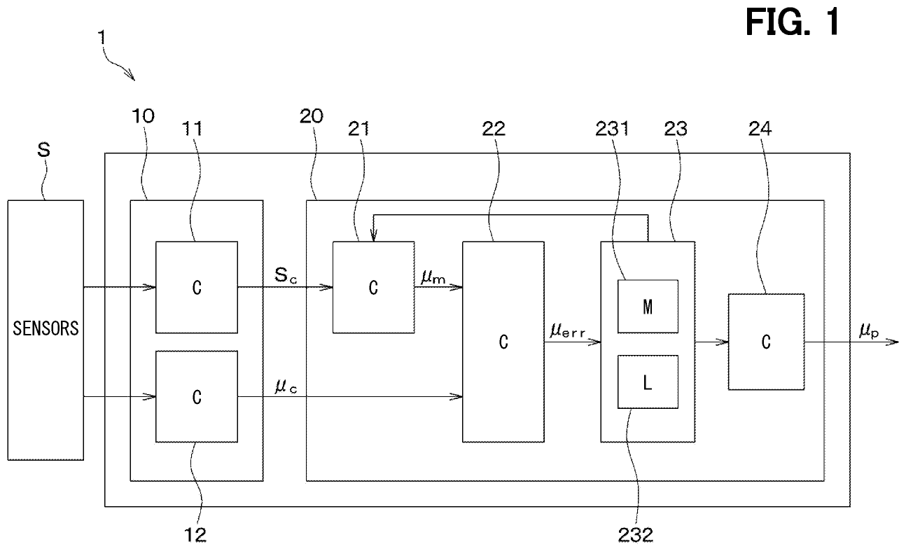

The present embodiment will be described with reference to FIGS. 1 to 11. A friction-coefficient-computing device of the present embodiment is used, for example, for a vehicle control system that controls traveling of an electric car. The vehicle control system is for controlling, for example, the rotation speed of the motor for driving the vehicle. As illustrated in FIG. 1, the vehicle control system includes a detection unit S that detects various types of information relating to the behavior of the vehicle, and a control device 1 that controls the rotation speed of the motor on the basis of the information detected by the detection unit S. The control device 1 is what is called an ECU. The control device 1 also functions as a friction-coefficient-computing device of the present embodiment. The ECU is the abbreviation for electronic control unit.

The detection unit S is a sensor group that detects, among information relating to the behavior of the vehicle, particularly, various types of information relating to the tire during the vehicle traveling on a road surface. The detection unit S is provided for the vehicle. Specifically, the detection unit S includes a vehicle speed sensor that detects the speed of the vehicle, a wheel speed sensor that detects the rotation speed of the tire, a steering-angle sensor that detects the rotation angle of the steering wheel, a yaw rate sensor that detects the angular rotation speed of the vehicle in a yaw direction, and an acceleration sensor that detects the acceleration of the vehicle. The detection unit S also includes a torque sensor that detects the magnitude of the torque applied to the tire, and a load sensor that detects the load generated in the tire. The detection unit S transmits, to the control device 1, detection signals corresponding to detected values detected by these various sensors.

The control device 1 includes a microcomputer including a central processing unit (CPU) and memories, such as a read-only memory (ROM) and a random-access memory (RAM), and a peripheral circuit of the microcomputer. The memories include non-transitory tangible storage media. The control device 1 performs various computations and processing on the basis of programs stored in the ROM. As illustrated in FIG. 1, the control device 1 includes a computing unit 10 and a maximum-friction-estimating unit 20.

If detection signals corresponding to detected values detected by the various sensors are input into the control device 1 from the detection unit S, the control device 1 executes programs stored in the ROM to function as the computing unit 10 and the maximum-friction-estimating unit 20. Alternatively, the control device 1 may include a plurality of circuit modules corresponding to, on a one-to-one basis, the computing unit 10 and the maximum-friction-estimating unit 20.

Hereinafter, the computing unit 10 and the maximum-friction-estimating unit 20 will be individually described. First, the computing unit 10 will be described. The computing unit 10 is a computing device that on the basis of various detection signals transmitted from the detection unit S, calculates a slip ratio and a friction coefficient between the tire and the road surface during occurrence of a slip between the tire and the road surface during the vehicle traveling on the road surface. The computing unit 10 includes a slip calculator 11 that calculates a slip ratio, and a friction calculator 12 that calculates a friction coefficient.

If detection signals corresponding to detected values detected by the various sensors are input into the slip calculator 11 from the detection unit S, on the basis of these detected values, the slip calculator 11 calculates a slip ratio between the tire and the road surface. For example, in a case where the vehicle travels straight, the slip calculator 11 calculates the slip ratio on the basis of the difference between the speed of the vehicle detected by the vehicle speed sensor and the rotation speed of the tire detected by the wheel speed sensor. For example, in a case where the vehicle skids laterally, the slip calculator 11 calculates the slip ratio on the basis of, in addition to the detected values detected by the vehicle speed sensor and the wheel speed sensor, the detected values detected by the steering-angle sensor, the yaw rate sensor, and the acceleration sensor. The slip calculator 11 has an output side connected to the maximum-friction-estimating unit 20. Information of a slip ratio calculated by the slip calculator 11 is transmitted to a model calculator 21, which will be described later, of the maximum-friction-estimating unit 20. Hereinafter, the slip ratio calculated by the slip calculator 11 is also referred to as a calculated slip ratio s_{c}.

If detection signals corresponding to detected values detected by the various sensors are input into the friction calculator 12 from the detection unit S, on the basis of these detected values, the friction calculator 12 calculates a friction coefficient of the road surface. For example, the friction calculator 12 calculates a friction coefficient on the basis of detected values detected by the torque sensor, the load sensor, and the acceleration sensor. The friction calculator 12 has an output side connected to the maximum-friction-estimating unit 20. Information of a friction coefficient calculated by the friction calculator 12 is transmitted to an error calculator 22, which will be described later, of the maximum-friction-estimating unit 20. Hereinafter, the friction coefficient calculated by the friction calculator 12 is also referred to as a calculated friction coefficient μ_{c}.

Although not illustrated, a noise filter is provided between the computing unit 10 and the maximum-friction-estimating unit 20. This noise filter includes, for example, a low-pass filter or the like. In a case where a calculated slip ratio s_{c} calculated by the slip calculator 11 and a calculated friction coefficient μ_{c} calculated by the friction calculator 12 include noise caused by vibration of the vehicle or the like, the noise filter removes the noise.

The maximum-friction-estimating unit 20 is a computing device that calculates an estimated maximum value of a friction coefficient between the tire and the road surface on the basis of information of a calculated slip ratio s_{c} transmitted from the slip calculator 11 and information of a calculated friction coefficient μ_{c} transmitted from the friction calculator 12. The maximum-friction-estimating unit 20 uses a tire brush model, which will be described later, to calculate an estimated maximum value of the friction coefficient. The maximum-friction-estimating unit 20 includes the model calculator 21, the error calculator 22, a parameter-estimating unit 23, and a maximum value calculator 24.

The model calculator 21 calculates a tire model friction μₘ, which is a theoretical estimated value of a friction coefficient in a tire brush model, which will be described later, on the basis of information of a calculated slip ratio s_{c} transmitted from the slip calculator 11. The model calculator 21 has an input side connected to the slip calculator 11. If information of a calculated slip ratio s_{c} is input into the model calculator 21 from the slip calculator 11, the model calculator 21 calculates a tire model friction μₘ on the basis of a tire brush model expression described later. The model calculator 21 has an output side connected to the error calculator 22. Information of a tire model friction μₘ calculated by the model calculator 21 is transmitted to the error calculator 22.

The error calculator 22 calculates a model error μₑᵣᵣ, which is the difference between a tire model friction μₘ calculated by the model calculator 21 and a calculated friction coefficient μ_{c} calculated by the friction calculator 12. The error calculator 22 calculates the difference between a tire model friction μₘ and a calculated friction coefficient μ_{c} calculated at the same timing as a calculated slip ratio s_{c} used for calculating the tire model friction μₘ, to calculate a model error μₑᵣᵣ.

If both information of a tire model friction μₘ is input from the model calculator 21, and information of a calculated friction coefficient μ_{c} is input from the friction calculator 12, the error calculator 22 calculates a model error μₑᵣᵣ, which is a difference value between the tire model friction μₘ and the calculated friction coefficient μ_{c}. The model error μₑᵣᵣ is a value obtained by subtracting the calculated friction coefficient μ_{c} from the tire model friction μₘ. The model error μₑᵣᵣ is calculated as an absolute value. The error calculator 22 has an output side connected to the parameter-estimating unit 23. Information of a model error μₑᵣᵣ calculated by the error calculator 22 is transmitted to the parameter-estimating unit 23.

On the basis of information of a model error μₑᵣᵣ transmitted from the error calculator 22, the parameter-estimating unit 23 estimates optimal parameters of the tire brush model expression to be described later. The parameter-estimating unit 23 includes an error-storing unit 231 and a parameter-restricting unit 232.

The error-storing unit 231 stores information transmitted from the error calculator 22. In other words, the error-storing unit 231 stores information relating to each of a calculated slip ratio s_{c} calculated by the slip calculator 11 and a calculated friction coefficient μ_{c} calculated by the friction calculator 12. The error-storing unit 231 is configured to be able to, every time the error-storing unit 231 acquires information of a model error μₑᵣᵣ from the error calculator 22, store the information of the model error μₑᵣᵣ.

The error-storing unit 231 stores information of a predetermined number, which is preliminarily determined, of model errors μₑᵣᵣ. The error-storing unit 231 of the present embodiment is configured to be able to store, for example, information of ten model errors μₑᵣᵣ. The number of pieces of information of model errors μₑᵣᵣ that can be stored in the error-storing unit 231 is not limited to ten, and may be fewer than ten or more than ten. In the present embodiment, the error-storing unit 231 functions as a parameter-storing unit.

When the parameter-estimating unit 23 estimates optimal parameters of the tire brush model expression to be described later, the parameter-restricting unit 232 limits the parameters to be estimated. The parameter-restricting unit 232 will be described in detail later.

The parameter-estimating unit 23 has an output side connected to the model calculator 21 and to the maximum value calculator 24. Information of optimal parameters estimated by the parameter-estimating unit 23 is output to the model calculator 21 and to the maximum value calculator 24.

On the basis of information of parameters of the tire brush model expression estimated by the parameter-estimating unit 23, the maximum value calculator 24 calculates an estimated maximum friction value μₚ, which is an estimated maximum value of the friction coefficient. If information of the parameters is input into the maximum value calculator 24 from the parameter-estimating unit 23, the maximum value calculator 24 calculates an estimated maximum friction value μₚ.

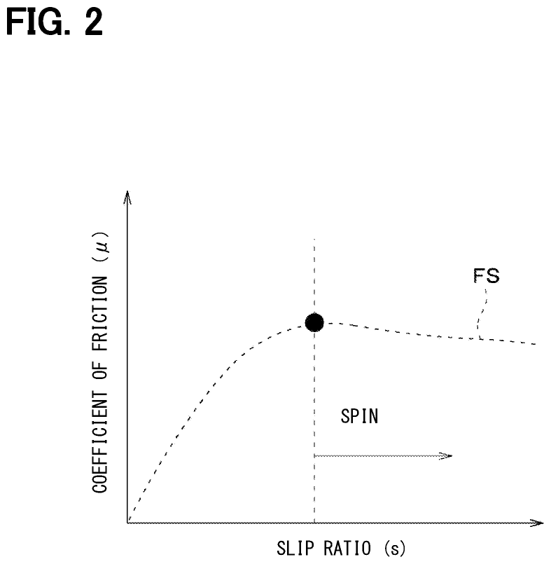

The friction coefficient has a correlation with the slip ratio, and the value of the friction coefficient varies according to a variation in the slip ratio. For example, as indicated by a friction-slip characteristic FS indicated by a broken line of FIG. 2, in an adhesive region where wheelspin of the tire does not occur, the friction coefficient during acceleration of the vehicle increases as the slip ratio increases. In the adhesive region, the friction coefficient is maximized when the value of the slip ratio increases until immediately before a start of wheelspin of the tire. In a wheelspin region where even slight wheelspin of the tire occurs, the value of the slip ratio gradually decreases as the slip ratio increases.

The friction coefficient during deceleration of the vehicle decreases as the slip ratio decreases in the adhesive region where wheelspin of the tire does not occur. A black circle illustrated in FIG. 2 indicates the slip ratio immediately before a start of wheelspin of the tire, that is, the maximum slip ratio in the adhesive region where wheelspin of the tire does not occur, and indicates the magnitude of the friction coefficient at a time of a maximum slip ratio in the adhesive region where wheelspin of the tire does not occur. As described above, the friction coefficient is maximized when the value of the slip ratio is maximized in the adhesive region. Hereinafter, the slip ratio at a time when the slip ratio is maximized in the adhesive region is also referred to as a maximum slip ratio.

The friction-slip characteristic FS indicating the friction coefficient and the slip ratio having such a correlation is similar to part of a graph indicated by the tire brush model expression. The tire brush model expression is a computation expression indicating a relationship among a slip ratio, a friction coefficient, a load generated in the tire, and the like in the tire brush model. Therefore, first, the tire brush model and the tire brush model expression will be described.

The tire brush model simulates a physical phenomenon in a contact region between a tire and a road surface, and is a tire model in which a plurality of brush-like elastic objects is attached to the tire. In a case where the tire brush model is used, the driving force generated in the tire can be expressed by the tire brush model expression shown in the following Formula 1.

$$Fd = H \frac{3 s}{1 + s} + HK \frac{- 3 {s}^{2}}{{( 1 + s )}^{2}} + {HK}^{2} \frac{{s}^{3}}{{( 1 + s )}^{3}} \qquad [ Formula 1 ]$$

Fd in Formula 1 represents the driving force generated in the tire. s in Formula 1 represents the slip ratio between the tire and the road surface. H in Formula 1 is a parameter that varies the inclination of the tire brush model expression shown in Formula 1. H in Formula 1 is determined on the basis of the length of the surface where the tire of the tire brush model is installed, the width of the surface where the tire is installed, and the shear rigidity of the brush in the tire front-rear direction. H in Formula 1 can be expressed as the following Formula 2.

$$H = \frac{{a}^{2} {bc}_{x}}{6} \qquad [ Formula 2 ]$$

K in Formula 1 is a parameter that varies the inclination of the tire brush model expression shown in Formula 1. K in Formula 1 is determined on the basis of the length of the surface where the tire is installed, the width of the surface where the tire is installed, the shear rigidity of the brush in the tire front-rear direction, and the friction coefficient between the tire and the road surface. K in Formula 1 can be expressed as the following Formula 3.

$$K = \frac{{a}^{2} {bc}_{x}}{6 {μ}_{p}} \qquad [ Formula 3 ]$$

a in Formulas 2 and 3 represents the length of the surface where the tire is installed in the tire brush model. b in Formulas 2 and 3 represents the width of the surface where the tire is installed in the tire brush model. Cₓ in Formulas 2 and 3 represents the shear rigidity of the brush in the tire front-rear direction in the tire brush model. μₚ in Formula 3 is an estimated maximum value of the friction coefficient, and indicates the friction coefficient in a case where the slip ratio is the maximum slip ratio.

The friction coefficient can be obtained by dividing the driving force generated in the tire by the normal force. Therefore, the tire model friction μₘ of the tire brush model can be calculated using the tire brush model expression shown in the following Formula 4 obtained by converting the tire brush model expression shown in Formula 1 using the normal force.

$${μ}_{m} = ( H \frac{3 s}{1 + S} + HK \frac{- 3 {s}^{2}}{{( 1 + s )}^{2}} + {HK}^{2} \frac{{s}^{3}}{{( 1 + s )}^{3}} ) / {F}_{Z} \qquad [ Formula 4 ]$$

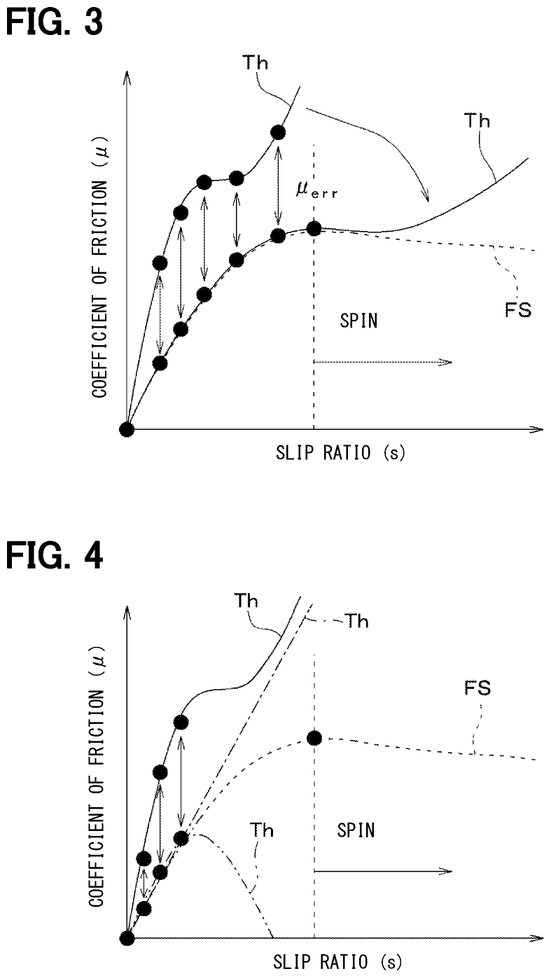

F_{z} in Formula 4 represents a normal force generated on the tire. The Formula 4 indicates the theoretical characteristic of the friction coefficient in the tire brush model. As shown in Formula 4, the tire model friction μₘ can be obtained using a computation expression including a cubic function relating to the slip ratio. The correspondence relationship between the tire model friction μₘ and the slip ratio shown in Formula 4 can be expressed as a theoretical characteristic Th indicated by a solid line of FIG. 3. However, as illustrated in FIG. 3, the theoretical characteristic Th may deviate from the friction-slip characteristic FS.

In such a case, as illustrated in FIG. 3, the theoretical characteristic Th can be brought closer to the friction-slip characteristic FS by changing H, HK, and HK², which are parameters of the tire brush model expression shown in Formula 4. The theoretical characteristic Th brought closer to the friction-slip characteristic FS can be used to obtain an estimated maximum friction value μₚ.

An example of a method for bringing the theoretical characteristic Th closer to the friction-slip characteristic FS will be described. First, a plurality of calculated slip ratios s_{c} is calculated on the basis of detection signals transmitted from the detection unit S, and the plurality of calculated slip ratios s_{c} that has been calculated is substituted into the tire brush model expression shown in Formula 4 to calculate a plurality of tire model frictions μₘ. As a result, a theoretical characteristic Th is obtained.

Then, model errors μₑᵣᵣ, which are, respectively, differences between the plurality of tire model frictions μₘ and a plurality of calculated friction coefficients μ_{c} calculated at the same timing as the plurality of calculated slip ratios s_{c} used to calculate the plurality of tire model frictions μₘ, are obtained. Then, H, HK, and HK², which are parameters of the tire brush model expression shown in Formula 4, are changed to make each of the obtained model errors μₑᵣᵣ smaller. That is, H, HK, and HK², which are parameters of the tire brush model expression shown in Formula 4, are changed so that the model errors μₑᵣᵣ approach zero.

As a result, even in a case where a theoretical characteristic Th deviates from the friction-slip characteristic FS, the theoretical characteristic Th can be brought closer to the friction-slip characteristic FS. The theoretical characteristic Th brought closer to the friction-slip characteristic FS can be used to obtain an estimated maximum friction value μₚ.

However, in a case where a theoretical characteristic Th is brought closer to the friction-slip characteristic FS using the above method to accurately calculate an estimated maximum friction value μₚ, a calculated slip ratio s_{c} calculated by the slip calculator 11 when the slip ratio increases to the maximum slip ratio is necessary. However, in order to increase the slip ratio to the maximum slip ratio, it is necessary to rotate the tire until immediately before a start of the wheelspin. It is not easy to rotate the tire until immediately before a start of the wheelspin.

In a case where the slip ratio does not increase to the maximum slip ratio, the slip calculator 11 cannot calculate a calculated slip ratio s_{c} at a time when the slip ratio increases to the maximum slip ratio. In this case, in the tire brush model expression shown in Formula 4, a theoretical characteristic Th cannot be accurately brought closer to the friction-slip characteristic FS, and it is difficult to accurately calculate an estimated maximum friction value μₚ.

For example, in a case where the vehicle is traveling in a state of a minute region where the slip ratio is 0.1 or less, which is sufficiently less than the slip ratio at which wheelspin of the tire starts, the slip calculator 11 calculates only values of the calculated slip ratio s_{c} in the minute region. In such a case, there is a possibility that an estimated maximum friction value μₚ cannot be obtained using the above method. Therefore, the inventor considered obtaining an estimated maximum friction value μₚ using the following method even in a case where the slip calculator 11 calculates only values of the calculated slip ratio s_{c} in the minute region that are smaller than the maximum slip ratio.

First, in a case where a value of the calculated slip ratio s_{c} is a value in the minute region that is sufficiently less than the slip ratio at which wheelspin of the tire starts, the slip ratio in the tire brush model can be expressed as the following Formula 5.

$$s \approx \frac{s}{1 + s} \qquad [ Formula 5 ]$$

Therefore, in a case where a value of the calculated slip ratio s_{c} is a value in the minute region, the tire brush model expression shown in Formula 4 can be replaced with the tire brush model expression shown in the following Formula 6.

μₘ=(H*3s−HK*3s²+HK²*s³)/F_{z} [Formula 6]

Formula 6 is a computation expression indicating the relationship between the slip ratio and the friction coefficient in the tire brush model. Formula 6 is a tire brush model expression for calculating an estimated friction coefficient between the tire and the road surface in a case where the slip ratio between the tire and the road surface is in a minute region where the slip ratio is less than the slip ratio at which wheelspin of the tire starts. Formula 6 includes a plurality of parameters that varies the inclination of the tire brush model expression.

In a case where a plurality of values of the calculated slip ratio s_{c} in the minute region is obtained by the slip calculator 11, the model calculator 21 substitutes the plurality of calculated slip ratios s_{c} into the tire brush model expression shown in Formula 6 to calculate a plurality of tire model frictions μₘ. As a result, even in a case where values of the calculated slip ratio s_{c} are values in the minute region, a theoretical characteristic Th can be obtained.

The parameter-estimating unit 23 calculates the values of H, HK, and HK², which are parameters of the tire brush model expression shown in Formula 6, so as to make the model errors μₑᵣᵣ smaller. For example, the parameter-estimating unit 23 obtains H in the first term, HK in the second term, and HK² in the third term of Formula 6 so that the model errors μₑᵣᵣ approach zero. As a result, the theoretical characteristic Th that can be obtained from the tire brush model expression shown in Formula 6 can be brought closer to the friction-slip characteristic FS.

In this manner, the inventor considered calculating an estimated maximum friction value μₚ using a theoretical characteristic Th brought closer to a friction-slip characteristic FS. However, further intensive consideration by the inventor revealed that in some cases, it is difficult to bring the theoretical characteristic Th closer to the friction-slip characteristic FS.

For example, in a case where in Formula 6, HK in the second term and HK² in the third term of the parameters obtained so that the model errors μₑᵣᵣ approach zero are zeros, Formula 6 is a linear function relating to the slip ratio.

On the other hand, in a friction-slip characteristic FS in a case of a minute region where the slip ratio is less than the slip ratio at which wheelspin of the tire starts, the friction coefficient increases substantially linearly as the slip ratio increases. That is, in the friction-slip characteristic FS in the minute region, the friction coefficient increases substantially in proportion to the slip ratio.

Therefore, in a case where the value of H in the first term of the tire brush model expression shown in Formula 6 is calculated so as to make the model errors μₑᵣᵣ smaller, the theoretical characteristic Th may be linear as illustrated by a dot-dash line of FIG. 4. That is, the optimal parameters for bringing the theoretical characteristic Th closer to the friction-slip characteristic FS include values for making the theoretical characteristic Th linear. In this case, since the theoretical characteristic Th and the friction-slip characteristic FS deviate from each other, an estimated maximum friction value μₚ cannot be accurately calculated.

Alternatively, in a case where in Formula 6, H in the first term and HK² in the third term of the parameters obtained so that the model errors μₑᵣᵣ approach zero are zeros, Formula 6 is a quadratic function relating to the slip ratio. In a case where the value of HK in the second term of the tire brush model expression shown in Formula 6 is calculated so as to make the model errors μₑᵣᵣ smaller, the theoretical characteristic Th may have an upwardly-convex parabolic shape as illustrated by a two-dots-dash line of FIG. 4. That is, the optimal parameters for bringing the theoretical characteristic Th closer to the friction-slip characteristic FS include values for obtaining a theoretical characteristic Th having an upwardly-convex parabolic shape. In this case, since the theoretical characteristic Th and the friction-slip characteristic FS deviate from each other, an estimated maximum friction value μₚ cannot be accurately calculated.

As described above, in a case where the values of H, HK, and HK² of the tire brush model expression shown in Formula 6 are calculated so as to make the model errors μₑᵣᵣ smaller, a theoretical characteristic Th from which an estimated maximum friction value μₚ cannot be accurately calculated may be obtained. That is, even if the values of H, HK, and HK² of the tire brush model expression are calculated to make the model errors μₑᵣᵣ smaller, there is a possibility that the theoretical characteristic Th and the friction-slip characteristic FS deviate from each other. In other words, the candidates for the values of H, HK, and HK² of the tire brush model expression for bringing the theoretical characteristic Th closer to the friction-slip characteristic FS include candidates from which an estimated maximum friction value μₚ cannot be accurately calculated. This was found through intensive consideration by the inventor.

Therefore, the inventor considered a method for, when the values of H, HK, and HK², which are parameters of the tire brush model expression, are estimated, excluding, from the candidates for the values of H, HK, and HK², candidates from which an estimated maximum friction value μₚ cannot be accurately calculated.

As illustrated in FIG. 2 and the like, in the friction-slip characteristic FS, the friction coefficient increases as the slip ratio increases, but as the slip ratio approaches the maximum slip ratio, the ratio of the increase in the friction coefficient decreases as the slip ratio increases. That is, in the friction-slip characteristic FS, the increase ratio of the friction coefficient gradually decreases as the slip ratio approaches the maximum slip ratio. If the slip ratio increases to a value substantially equal to the maximum slip ratio, the friction coefficient substantially does not vary and becomes constant even if the slip ratio increases. In other words, the friction-slip characteristic FS has a shape having a staying portion where a ratio of a variation in the friction coefficient to an increase in the slip ratio is zero when the slip ratio is a substantially maximum slip ratio.

Therefore, in a case where the theoretical characteristic Th is approximated to the friction-slip characteristic FS, a graph where the tire brush model expression shown in Formula 6 is expressed by a cubic function relating to the slip ratio has a shape in which the friction coefficient increases as the slip ratio increases. The graph where the tire brush model expression shown in Formula 6 is expressed by a cubic function relating to the slip ratio also has a shape that does not have a maximum value and a minimum value, and has only one staying portion where the ratio of the variation in the friction coefficient relative to the increase in the slip ratio is zero. That is, the graph has one portion where the inclination at the inflection point is zero.

The inclination in the cubic function relating to the slip ratio shown in Formula 6 can be expressed as the following Formula 7 obtained by differentiating Formula 6 with the slip ratio.

μₘ′=(3H−3HK*s+HK²*s²)/F_{z} [Formula 7]

Since the cubic function relating to the slip ratio shown in Formula 6 has one portion where the inclination is zero, the relationship among H, HK, and HK² can be expressed in Formula 8, which is the discriminant of Formula 7, as follows:

D=(3HK)²−3H*(3HK²)=0 [Formula 8]

Formula 8 is used for HK² in the third term of Formula 6, so that H in the first term and HK in the second term can be used to express Formula 6 as the following Formula 9.

HK²=(HK)²/H [Formula 9]

HK² in Formula 9 is substituted into the tire brush model expression shown in Formula 6, so that Formula 6 can be replaced with the following Formula 10.

μₘ=(H*3s−HK*3s²+((HK²)/H)*s³)/F_{z} [Formula 10]

Formula 6 is replaced with Formula 10 in this manner, so that when the parameters of the tire brush model expression are estimated, it is possible to exclude, from candidates for the values of the parameters, candidates from which an estimated maximum friction value μₚ cannot be accurately calculated. Therefore, as illustrated in FIG. 1, the parameter-estimating unit 23 of the present embodiment includes the parameter-restricting unit 232 for excluding, from candidates for the values of the parameters, candidates from which an estimated maximum friction value μₚ cannot be accurately calculated. The parameter-restricting unit 232 is a formula-converting unit that converts Formula 6, which is a tire brush model expression, into Formula 10. When the parameter-estimating unit 23 estimates the optimal parameters of the tire brush model expression, the parameter-restricting unit 232 limits the values of the parameters.

Specifically, the parameter-restricting unit 232 of the present embodiment eliminates the values of the parameters that allow the tire brush model expression shown in Formula 6 to be a linear function and a quadratic function, and obtains the values of the parameters that allow the inclination of the inflection point of the tire brush model expression to be zero. The parameter-restricting unit 232 restricts the values of the parameters to satisfy the relationship of the above Formula 9 in terms of H, HK, and HK², which are parameters of the tire brush model expression shown in Formula 6.

The parameter-estimating unit 23 of the present embodiment calculates the values of H and HK, which are parameters of the tire brush model expression shown in Formula 10, so as to make smaller model errors μₑᵣᵣ calculated by the error calculator 22. For example, the parameter-estimating unit 23 obtains H in the first term and HK in the second term of Formula 10 so that the model errors μₑᵣᵣ approach zero. As a result, the theoretical characteristic Th that can be obtained from the tire brush model expression shown in Formula 10 can be brought closer to the friction-slip characteristic FS. For such theoretical characteristics Th that can be obtained in this way, a theoretical characteristic Th from which an estimated maximum friction value μₚ cannot be accurately calculated is excluded. The parameter-estimating unit 23 outputs information of the calculated values of H and HK, which are parameters of the tire brush model expression, to the model calculator 21 and to the maximum value calculator 24.

The maximum value calculator 24 calculates an estimated maximum friction value μₚ on the basis of the information of the values of H and HK, which are parameters of the tire brush model expression and have been calculated by the parameter-estimating unit 23.

The estimated maximum friction value μₚ can be obtained on the basis of Formulas 2 and 3 and using the following Formula 11.

$${μ}_{p} = \frac{{H}^{2}}{HK} \qquad [ Formula 11 ]$$

H and HK in Formula 11 are parameter values estimated by the parameter-estimating unit 23 to be able to bring the theoretical characteristic Th closer to the friction-slip characteristic FS. Therefore, an estimated maximum friction value μₚ can be calculated on the basis of Formula 11 and the values of H and HK, which are parameters of the tire brush model expression and have been calculated by the parameter-estimating unit 23.

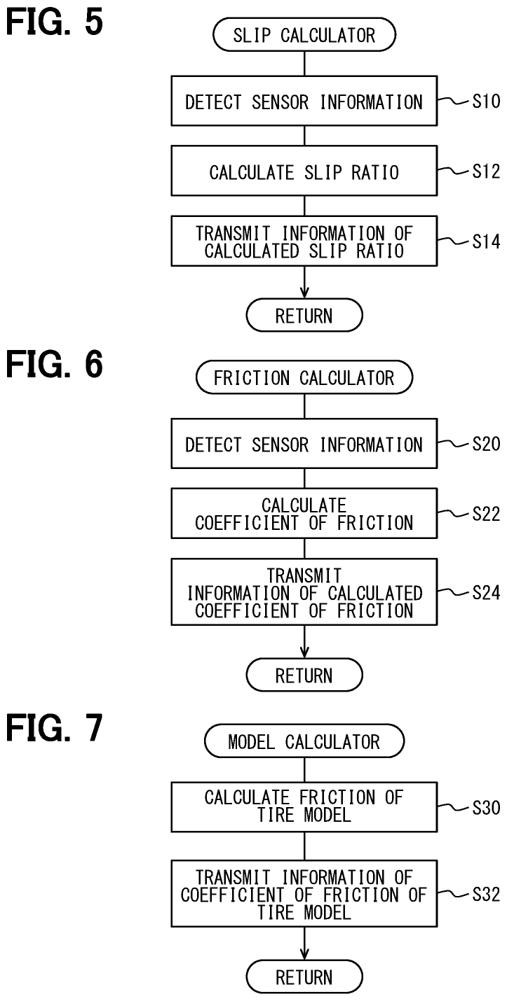

Next, an example of control processing executed by the control device 1 will be described with reference to flowcharts illustrated in FIGS. 5 to 10. The control device 1 repeatedly executes each control processing illustrated in FIGS. 5 to 10 in every predetermined control cycle preliminarily determined.

First, processing executed by the slip calculator 11 illustrated in FIG. 5, which is part of the control processing executed by the control device 1, will be described. The slip calculator 11 repeatedly executes the processing illustrated in FIG. 5 in every predetermined control cycle in order to calculate calculated slip ratios s_{c}.

First, in step S10, the slip calculator 11 detects, among detection signals transmitted from the detection unit S, information necessary to calculate a calculated slip ratio s_{c}. For example, in a case where the vehicle travels straight, the information necessary to calculate a calculated slip ratio s_{c} is information of the speed of the vehicle detected by the vehicle speed sensor, and information of the rotation speed of the tire detected by the wheel speed sensor.

In step S12, the slip calculator 11 calculates a calculated slip ratio s_{c} on the basis of the information necessary to calculate the calculated slip ratio s_{c}. In step S14, the slip calculator 11 transmits information of the calculated slip ratio s_{c} to the model calculator 21.

Next, processing executed by the friction calculator 12 illustrated in FIG. 6, which is part of the control processing executed by the control device 1, will be described. The friction calculator 12 repeatedly executes the processing illustrated in FIG. 6 in every predetermined control cycle in order to calculate calculated friction coefficients μ_{c}.

First, in step S20, the friction calculator 12 detects, among detection signals transmitted from the detection unit S, information necessary to calculate a calculated friction coefficient μ_{c}. The information necessary to calculate a calculated friction coefficient μ_{c} is, for example, information of the torque applied to the tire detected by the torque sensor, information of the load generated in the tire detected by the load sensor, and information of the acceleration of the vehicle detected by the acceleration sensor.

In step S22, the friction calculator 12 calculates a calculated friction coefficient μ_{c} on the basis of the information necessary to calculate the calculated friction coefficient μ_{c}. The timing at which the friction calculator 12 executes the processing illustrated in FIG. 6 is the same timing as the timing at which the slip calculator 11 executes the processing illustrated in FIG. 5. Therefore, the friction calculator 12 calculates calculated friction coefficients μ_{c} in the same control cycle as the control cycle in which the slip calculator 11 performs the processing for calculating calculated slip ratios s_{c}.

In step S24, the friction calculator 12 transmits information of the calculated friction coefficient μ_{c} to the error calculator 22.

Next, processing executed by the model calculator 21 illustrated in FIG. 7, which is part of the control processing executed by the control device 1, will be described. The model calculator 21 repeatedly executes the processing illustrated in FIG. 7 every time information of a calculated slip ratio s_{c} is input from the slip calculator 11.

If information of a calculated slip ratio s_{c} is input from the slip calculator 11, in step S30, the model calculator 21 calculates a tire model friction μₘ on the basis of Formula 6 and the information of the calculated slip ratio s_{c} transmitted from the slip calculator 11. Specifically, the model calculator 21 substitutes the calculated slip ratio s_{c} into Formula 6 of the tire brush model expression to perform the computation to calculate a tire model friction μₘ. In step S32, the model calculator 21 transmits information of the calculated tire model friction μₘ to the error calculator 22.

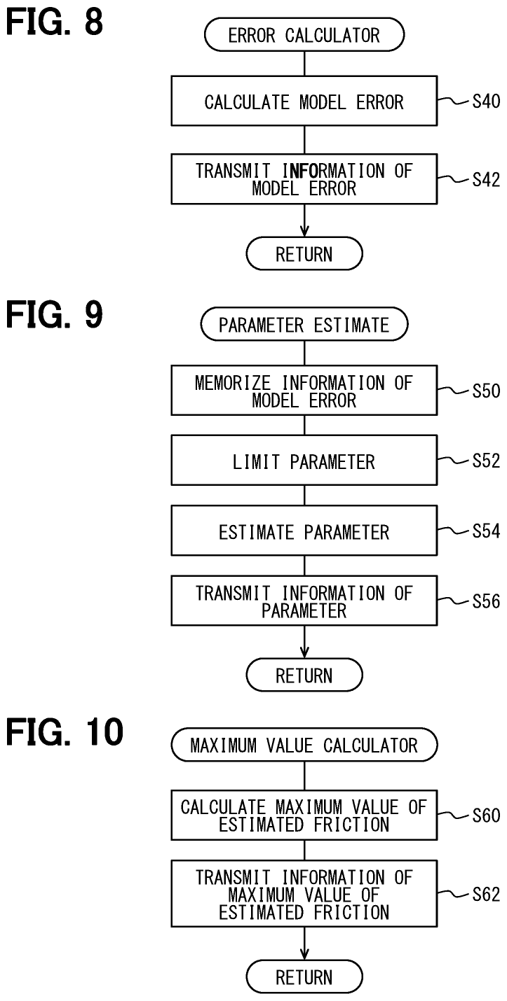

Next, processing executed by the error calculator 22 illustrated in FIG. 8, which is part of the control processing executed by the control device 1, will be described. The error calculator 22 repeatedly executes the processing illustrated in FIG. 8 every time both information of a tire model friction μₘ is input from the model calculator 21 and information of a calculated friction coefficient μ_{c} is input from the friction calculator 12.

In step S40, the error calculator 22 calculates, as a model error μₑᵣᵣ, an absolute value of a value obtained by subtracting the calculated friction coefficient μ_{c} from the tire model friction μₘ.

As described above, the processing in which the slip calculator 11 calculates a calculated slip ratio s_{c} and the processing in which the friction calculator 12 calculates a calculated friction coefficient μ_{c} are repeatedly executed in the same control cycle. Therefore, a model error μₑᵣᵣ calculated by the error calculator 22 is an error between a tire model friction μₘ and a calculated friction coefficient μ_{c} calculated on the basis of a calculated slip ratio s_{c} calculated in the same control cycle.

In step S42, the error calculator 22 transmits information of the calculated model error μₑᵣᵣ to the parameter-estimating unit 23.

Next, processing executed by the parameter-estimating unit 23 illustrated in FIG. 9, which is part of the control processing executed by the control device 1, will be described. The parameter-estimating unit 23 repeatedly executes the processing illustrated in FIG. 9 every time information of a model error μₑᵣᵣ is input from the error calculator 22.

If information of a model error μₑᵣᵣ is input from the error calculator 22, the parameter-estimating unit 23 stores the input information of the model error μₑᵣᵣ in the error-storing unit 231 in step S50. The parameter-estimating unit 23 of the present embodiment is configured to be able to store ten pieces of information of model errors μₑᵣᵣ in the error-storing unit 231. Therefore, the parameter-estimating unit 23 stores information of a model error μₑᵣᵣ input into the parameter-estimating unit 23 every time the processing illustrated in FIG. 9 is executed (that is, in every control cycle).

In a case where the processing of step S50 is executed in a state where the error-storing unit 231 stores ten pieces of information of model errors μₑᵣᵣ, the parameter-estimating unit 23 erases, among the ten pieces of information of the old model errors μₑᵣᵣ, the information of the oldest model error μₑᵣᵣ. Then, the parameter-estimating unit 23 stores newly input information of a model error μₑᵣᵣ in the error-storing unit 231. That is, the error-storing unit 231 updates one piece of stored information of a model error μₑᵣᵣ each time the error-storing unit 231 acquires one piece of information of a model error μₑᵣᵣ from the error calculator 22.

Next, in step S52, the parameter-estimating unit 23 limits the parameters at the time of the estimation of the parameters of the tire brush model expression. As described above, the parameters of the tire brush model expression shown in Formula 6 include candidates from which an estimated maximum friction value μₚ cannot be accurately calculated. Therefore, in step S52, the parameter-restricting unit 232 excludes, from candidates for the parameters of the tire brush model expression shown in Formula 6, candidates from which an estimated maximum friction value μₚ cannot be accurately calculated. Specifically, the parameter-restricting unit 232 replaces the tire brush model expression shown in Formula 6 with the tire brush model expression shown in Formula 10.

Then, in step S54, the parameter-estimating unit 23 obtains H of the first term and HK of the second term, which are parameters of Formula 10, so that model errors μₑᵣᵣ stored in the error-storing unit 231 approach zero. For example, in a case where the error-storing unit 231 stores ten pieces of information of model errors μₑᵣᵣ, the parameter-estimating unit 23 obtains H of the first term and HK of the second term, which are parameters of Formula 10, so that each of the ten model errors μₑᵣᵣ approaches zero.

As a method for obtaining H and HK so that the model errors μₑᵣᵣ approach zero, for example, a method using an adaptive filter can be employed. Specifically, the adaptive filter may use recursive least squares or a Kalman filter.

As a result, the theoretical characteristic Th that can be obtained from the tire brush model expression shown in Formula 10 can be brought closer to the friction-slip characteristic FS. For such theoretical characteristics Th that can be obtained in this way, a theoretical characteristic Th from which an estimated maximum friction value μₚ cannot be accurately calculated is excluded.

In step S56, the parameter-estimating unit 23 transmits information of the calculated values of H and HK to the model calculator 21 and to the maximum value calculator 24.

The parameter-estimating unit 23 transmits information of the calculated values of H and HK to the model calculator 21 to update the tire brush model expression shown in Formula 6 used when in step S30, the model calculator 21 calculates a tire model friction μₘ. Therefore, in the processing of step S30 executed in a control cycle executed after the processing of step S56 is executed, the model calculator 21 calculates a tire model friction μₘ on the basis of the information of the parameter values transmitted from the parameter-estimating unit 23. Specifically, the model calculator 21 calculates a tire model friction μₘ, in a state where each of the values of H in the first term, HK in the second term, and HK² in the third term of Formula 6 is updated with the value of H and the value of HK transmitted from the parameter-estimating unit 23.

Next, processing executed by the maximum value calculator 24 illustrated in FIG. 10, which is part of the control processing executed by the control device 1, will be described. The maximum value calculator 24 repeatedly executes the processing illustrated in FIG. 10 each time information of the values of H and HK is input from the parameter-estimating unit 23.

If information of the values of H and HK is input from the parameter-estimating unit 23, in step S60, the maximum value calculator 24 calculates an estimated maximum friction value μₚ on the basis of Formula 11 and the information of the values of H and HK input from the parameter-estimating unit 23. Specifically, the maximum value calculator 24 substitutes the values of H and HK into Formula 11 to perform the computation to calculate an estimated maximum friction value μₚ.

The maximum value calculator 24 calculates an estimated maximum friction value μₚ each time information of the values of H and HK is input from the parameter-estimating unit 23. Each time both the slip calculator 11 calculates a calculated slip ratio s_{c} and the friction calculator 12 calculates a calculated friction coefficient μ_{c} in every predetermined control cycle, the parameter-estimating unit 23 estimates the values of H and HK, and transmits the estimated information to the maximum value calculator 24.

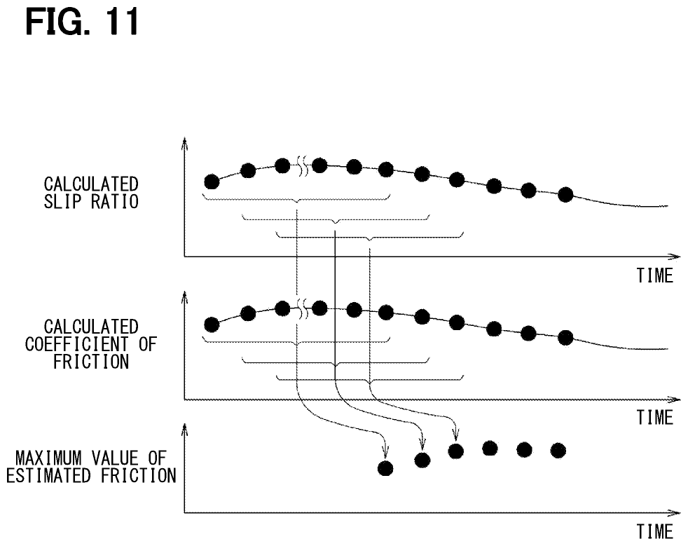

Therefore, as illustrated in FIG. 11, each time the slip calculator 11 detects, from the detection unit S, information necessary to calculate a calculated slip ratio s_{c}, and the friction calculator 12 detects, from the detection unit S, information necessary to calculate a calculated friction coefficient μ_{c}, the maximum value calculator 24 calculates an estimated maximum friction value μₚ. In other words, each time information of a model error μₑᵣᵣ stored in the error-storing unit 231 and calculated on the basis of a calculated slip ratio s_{c} and a calculated friction coefficient μ_{c} is updated, the maximum value calculator 24 calculates an estimated maximum friction value μₚ.

In step S62, the maximum value calculator 24 outputs information of the calculated estimated maximum friction value μₚ to, for example, a motor-driving circuit that controls the rotation speed of the motor for driving the vehicle. As a result, when the control device 1 controls the rotation speed of the motor for driving the vehicle, the information of the estimated maximum friction value μₚ calculated by the friction-coefficient-computing device can be used.

As described above, the control device 1 of the present embodiment includes the maximum-friction-estimating unit 20 that calculates an estimated maximum friction value μₚ using a calculated slip ratio s_{c} and a calculated friction coefficient μ_{c}, and a tire brush model expression for calculating a friction coefficient in a case where the slip ratio is in a minute region. The tire brush model expression is a function relating to the slip ratio of the tire brush model, and includes a plurality of parameters that varies the inclination of the inflection point of the tire brush model expression. The maximum-friction-estimating unit 20 includes the model calculator 21 that substitutes a calculated slip ratio s_{c} into the tire brush model expression to calculate a tire model friction μₘ, and the parameter-estimating unit 23 that estimates the values of the parameters so as to make smaller the difference between the calculated friction coefficient μ_{c} and the tire model friction μₘ. The parameter-estimating unit 23 includes the parameter-restricting unit 232 that obtains the values of the parameters so as to eliminate the value of the parameter that allows the tire brush model expression to be a linear function and a quadratic function and so as to allow the inclination of the inflection point of the tire brush model expression to be zero.

Consequently, when the parameters of a tire brush model expression for calculating a friction coefficient in a case where the slip ratio is in a minute region are estimated, it is possible to exclude, from candidates for the values of the parameters, candidates from which an estimated maximum friction value μₚ cannot be accurately calculated. Therefore, even in a case where the slip calculator 11 can calculate only values of the calculated slip ratio s_{c} in the minute region, the theoretical characteristic Th that can be obtained from the tire brush model expression can be brought closer to the friction-slip characteristic FS. An estimated maximum friction value μₚ can be accurately calculated on the basis of the values of the parameters estimated to be able to bring the theoretical characteristic Th closer to the friction-slip characteristic FS.

According to the above embodiment, the following effects can be obtained.

(1) In the above embodiment, in the tire brush model expression shown in the above Formula 6, the parameters of the tire brush model expression are indicated by H, HK, and HK² in Formula 6. The parameter-restricting unit 232 restricts the values of the parameters to satisfy the relationship of the above Formula 9 in terms of the parameters.

As shown in Formula 11, an estimated maximum friction value μₚ can be calculated on the basis of H and HK, which are parameters in Formula 6. Therefore, an estimated maximum friction value μₚ can be easily calculated as compared with a case where H, HK, and HK², which are parameters in the above Formula 6, are defined by a relational expression different from Formula 9.

(2) In the above embodiment, the parameter-estimating unit 23 includes the error-storing unit 231 that acquires information of a model error μₑᵣᵣ relating to each of a calculated slip ratio s_{c} and a calculated friction coefficient μ_{c}. The error-storing unit 231 stores only ten pieces of acquired information of model errors μₑᵣᵣ. The parameter-estimating unit 23 estimates the values of the parameters of the tire brush model expression using a plurality of pieces of information of model errors μₑᵣᵣ stored in the error-storing unit 231.

Each time the error-storing unit 231 acquires one piece of information of a model error μₑᵣᵣ relating to each of a calculated slip ratio s_{c} and a calculated friction coefficient μ_{c}, the error-storing unit 231 updates one piece of stored information of a model error μₑᵣᵣ.

Consequently, when the parameter-estimating unit 23 estimates the values of the parameters of the tire brush model expression, the parameter-estimating unit 23 can estimate the values of the parameters using information of model errors μₑᵣᵣ in addition to the updated information of the model error μₑᵣᵣ. Therefore, it is possible to suppress the power consumption of the parameter-estimating unit 23 and to increase the processing speed at the time of the estimation of the values of the parameters as compared with a case where all pieces of information of model errors μₑᵣᵣ used at the time of the estimation of the value of the parameter are updated for each estimation.

### Modification of First Embodiment

In the first embodiment described above, an example has been described in which the parameter-estimating unit 23 estimates the values of the parameters of the tire brush model expression each time the error-storing unit 231 acquires, from the error calculator 22, one piece of information of a model error μₑᵣᵣ, but the example is not limitative. For example, the parameter-estimating unit 23 may be configured to estimate the values of the parameters of the tire brush model expression each time the error-storing unit 231 acquires, from the error calculator 22, a plurality of (for example, two) pieces of information of model errors μₑᵣᵣ.

### Second Embodiment

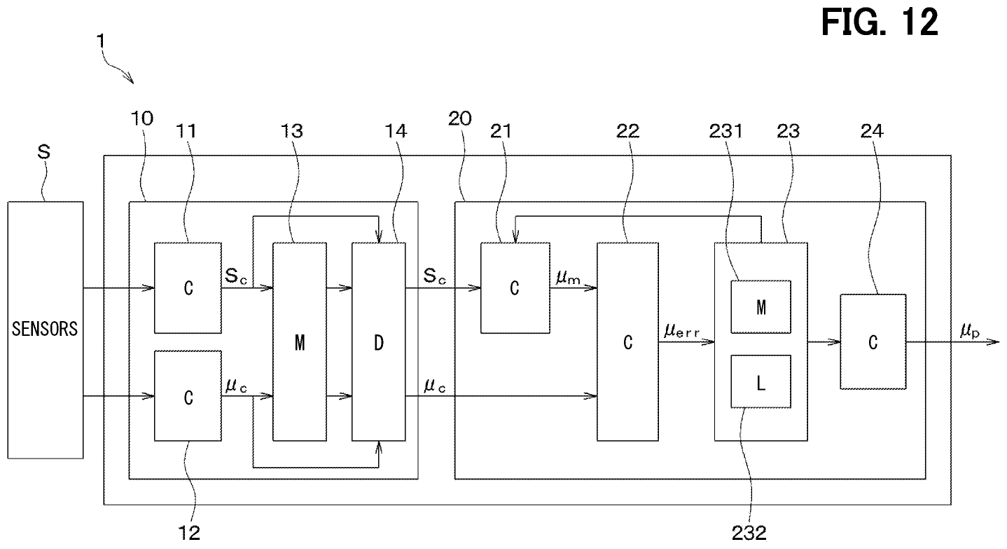

Next, a second embodiment will be described with reference to FIGS. 12 to 17. The present embodiment is different from the first embodiment in that a computing unit 10 includes a calculation memory 13 and a calculation determiner 14. Further, the present embodiment is different from the first embodiment in part of control processing executed by the computing unit 10. Except the differences, the present embodiment is similar to the first embodiment. Therefore, in the present embodiment, the portions different from those of the first embodiment will be mainly described, and description of the portions similar to those of the first embodiment may be omitted.

As illustrated in FIG. 12, the computing unit 10 includes the calculation memory 13 and the calculation determiner 14 in addition to a slip calculator 11 and a friction calculator 12.

The calculation memory 13 stores information of calculated slip ratios s_{c} calculated by the slip calculator 11, and information of calculated friction coefficients μ_{c} calculated by the friction calculator 12. The calculation memory 13 stores information of a calculated slip ratio s_{c} and information of a calculated friction coefficient μ_{c} that have been calculated in the same control cycle, and are associated with each other in the calculation memory 13.

The calculation memory 13 stores the predetermined number, which has been preliminarily determined, of pieces of information of calculated slip ratios s_{c} and pieces of information of calculated friction coefficients μ_{c}. The calculation memory 13 of the present embodiment is configured to be able to store, for example, ten pieces of information of calculated slip ratios s_{c} and ten pieces of information of calculated friction coefficients μ_{c} that are associated with each other in the calculation memory 13. The calculation memory 13 may be configured to be able to store fewer than ten pieces of information of calculated slip ratios s_{c} and fewer than ten pieces of information of calculated friction coefficients μ_{c}, or may be configured to be able to store more than ten pieces of information of calculated slip ratios s_{c} and more than ten pieces of information of calculated friction coefficients μ_{c}.

The calculation determiner 14 determines whether a calculated slip ratio s_{c} calculated by the slip calculator 11 and a calculated friction coefficient μ_{c} calculated by the friction calculator 12 are normal. On the basis of the information of calculated slip ratios s_{c} and the information of calculated friction coefficients μ_{c} stored in the calculation memory 13, the calculation determiner 14 determines whether the calculated slip ratios s_{c} calculated by the slip calculator 11 and the calculated friction coefficients μ_{c} calculated by the friction calculator 12 are normal.

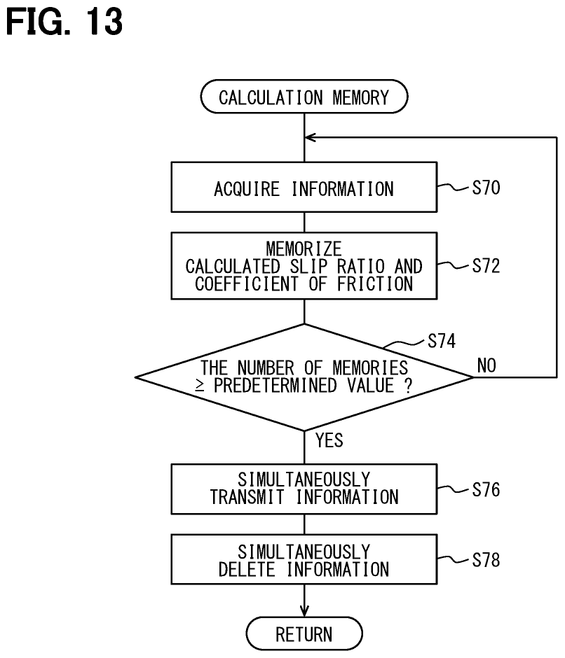

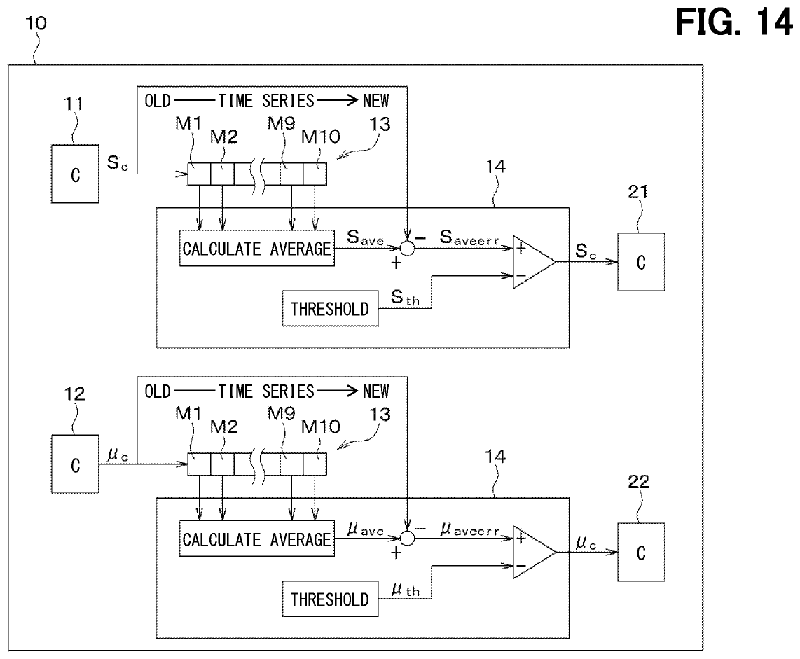

Next, control processing executed by the calculation memory 13 will be described with reference to FIG. 13. The calculation memory 13 repeatedly executes the processing illustrated in FIG. 13 each time both information of a calculated slip ratio s_{c} is input from the slip calculator 11 and information of a calculated friction coefficient μ_{c} is input from the friction calculator 12.

First, in step S70, the calculation memory 13 acquires information of a calculated slip ratio s_{c} from the slip calculator 11, and acquires information of a calculated friction coefficient μ_{c} from the friction calculator 12. If the calculation memory 13 acquires information of a calculated slip ratio s_{c} from the slip calculator 11 and information of a calculated friction coefficient μ_{c} from the friction calculator 12, in step S72, the calculation memory 13 stores the input information of the calculated slip ratio s_{c} and the input information of the calculated friction coefficient μ_{c}. When storing information of a calculated slip ratio s_{c} and information of a calculated friction coefficient μ_{c}, the calculation memory 13 stores the information of the calculated slip ratio s_{c} and the information of the calculated friction coefficient μ_{c} that have been calculated in the same control cycle and are associated with each other in the calculation memory 13.

Then, in step S74, the calculation memory 13 determines whether the number of pieces of information of calculated slip ratios s_{c} and the number of pieces of information of calculated friction coefficients μ_{c} stored in the calculation memory 13 are equal to or more than a predetermined number preliminarily determined. The calculation memory 13 of the present embodiment is configured to be able to store ten pieces of information of calculated slip ratios s_{c} and ten pieces of information of calculated friction coefficients μ_{c}. Therefore, in step S74, the calculation memory 13 determines whether the number of pieces of information of calculated slip ratios s_{c} and the number of pieces of information of calculated friction coefficients μ_{c} stored in the calculation memory 13 are ten or more. The calculation memory 13 repeatedly executes the processing of steps S70 and S72 until the number of pieces of information of calculated slip ratios s_{c} and the number of pieces of information of calculated friction coefficients μ_{c} stored in the calculation memory 13 amount to ten or more.

As illustrated in FIG. 14, the calculation memory 13 of the present embodiment includes a first address M1 to a 10th address M10 in which ten pieces of information of calculated slip ratios s_{c} and ten pieces of information of calculated friction coefficients μ_{c} are stored and associated with each other. If pieces of information of calculated slip ratios s_{c} and pieces of information of calculated friction coefficients μ_{c} are input, the calculation memory 13 stores the pieces of information of the calculated slip ratios s_{c} and the pieces of information of the calculated friction coefficients μ_{c} in the first address M1 to the 10th address M10 in the order of the input. That is, the calculation memory 13 stores the pieces of information of the calculated slip ratios s_{c} and the pieces of information of the calculated friction coefficients μ_{c} in the first address M1 to the 10th address M10 in chronological order.

In the calculation memory 13 of the present embodiment, information of the oldest calculated slip ratio s_{c} and information of the oldest calculated friction coefficient μ_{c} are input in the first address M1. The calculation memory 13 of the present embodiment is configured such that pieces of information of newer calculated slip ratios s_{c} and pieces of information of newer calculated friction coefficients μ_{c} are input in the first address M1 to the 10th address M10 in this order.

If it is determined that the number of stored pieces of information of calculated slip ratios s_{c} and the number of stored pieces of information of calculated friction coefficients μ_{c} are ten or more, in step S76, the calculation memory 13 collectively transmits the ten pieces of information of the calculated slip ratios s_{c} and the ten pieces of information of the calculated friction coefficients μ_{c} to the calculation determiner 14. Then, in step S78, the calculation memory 13 collectively erases the ten pieces of transmitted information of the calculated slip ratios s_{c} and the ten pieces of transmitted information of the calculated friction coefficients μ_{c}.

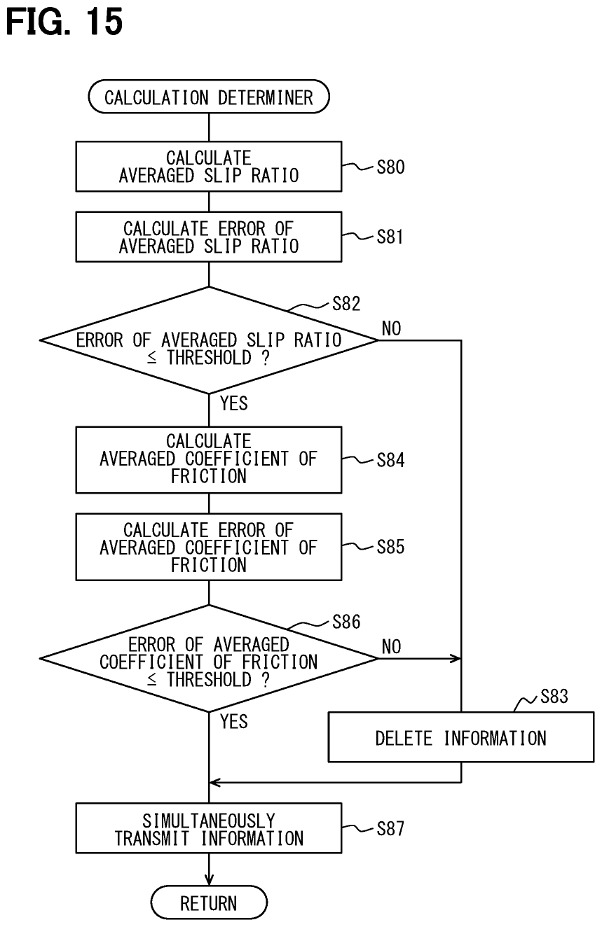

Next, control processing executed by the calculation determiner 14 will be described with reference to FIG. 15. The calculation determiner 14 repeatedly executes the processing illustrated in FIG. 15 each time each of the ten pieces of information of calculated slip ratios s_{c} and the ten pieces of information of calculated friction coefficients μ_{c} are input from the calculation memory 13.

If the ten pieces of information of calculated slip ratios s_{c} are input from the calculation memory 13, in step S80, the calculation determiner 14 calculates an averaged slip ratio sₐᵥₑ, which is the averaged value of the ten calculated slip ratios s_{c}.

In step S81, the calculation determiner 14 calculates ten averaged-slip-ratio errors sₐᵥₑₐᵣᵣ, which are difference values between each of the ten calculated slip ratios s_{c} and the averaged slip ratio sₐᵥₑ. The averaged-slip-ratio error sₐᵥₑₐᵣᵣ is a value obtained by subtracting each of the ten calculated slip ratios s_{c} from the averaged slip ratio sₐᵥₑ, and is calculated as an absolute value.

In step S82, on the basis of each of the ten calculated averaged-slip-ratio errors sₐᵥₑₐᵣᵣ, the calculation determiner 14 determines whether each of the ten calculated slip ratios s_{c} is normal. Specifically, the calculation determiner 14 determines whether each of the ten calculated averaged-slip-ratio errors sₐᵥₑₐᵣᵣ is equal to or less than a slip ratio threshold sₜₕ.

In a case where a calculated averaged-slip-ratio error sₐᵥₑₐᵣᵣ is equal to or less than the slip ratio threshold sₜₕ, the calculation determiner 14 determines that the calculated slip ratio s_{c} corresponding to the averaged-slip-ratio error sₐᵥₑₐᵣᵣ determined to be equal to or less than the slip ratio threshold sₜₕ is normal. On the other hand, in a case where a calculated averaged-slip-ratio error sₐᵥₑₐᵣᵣ is not equal to or less than the slip ratio threshold sₜₕ, the calculation determiner 14 determines that the calculated slip ratio s_{c} corresponding to the averaged-slip-ratio error sₐᵥₑₐᵣᵣ determined to be not equal to or less than the slip ratio threshold sₜₕ is abnormal.

The slip ratio threshold sₜₕ is an evaluated maximum value of an allowable variation amount of a calculated slip ratio s_{c} in a case where a plurality of calculated slip ratios s_{c} is calculated on the basis of the information detected from the detection unit S in a predetermined control cycle. The slip ratio threshold sₜₕ is preliminarily set in the calculation determiner 14, and can be obtained by, for example, a preliminarily performed experiment.

In step S83, the calculation determiner 14 erases, among the ten calculated slip ratios s_{c}, information of a calculated slip ratio s_{c} whose averaged-slip-ratio error sₐᵥₑₐᵣᵣ has been determined to be not equal to or less than the slip ratio threshold sₜₕ, and erases information of the calculated friction coefficient μ_{c} associated with the calculated slip ratio s_{c} in question.

In a case where it is determined that all the ten calculated slip ratios s_{c} are abnormal, the calculation determiner 14 erases all the ten pieces of information of the calculated slip ratios s_{c} and the calculated friction coefficients μ_{c} stored in the calculation memory 13. On the other hand, in a case where it is determined that at least one of the ten calculated slip ratios s_{c} is normal, in step S84, the calculation determiner 14 calculates an averaged friction coefficient μₐᵥₑ, which is the averaged value of the ten calculated friction coefficients μ_{c}.

In step S85, the calculation determiner 14 calculates an averaged-friction-coefficient error μₐᵥₑₐᵣᵣ, which is a difference value between the averaged friction coefficient μₐᵥₑ and each calculated friction coefficient μ_{c} associated with the calculated slip ratio s_{c} that has not been determined to be abnormal. The averaged-friction-coefficient error μₐᵥₑₐᵣᵣ is a value obtained by subtracting each calculated friction coefficient μ_{c} from the averaged friction coefficient μₐᵥₑ, and is calculated as an absolute value.

In step S86, on the basis of the one calculated averaged-friction-coefficient error μₐᵥₑₐᵣᵣ or on the basis of each of the plurality of calculated averaged-friction-coefficient errors μₐᵥₑₐᵣᵣ, the calculation determiner 14 determines whether each calculated friction coefficient μ_{c} associated with the calculated slip ratio s_{c} that has not been determined to be abnormal is normal. Specifically, the calculation determiner 14 determines whether each of the calculated averaged-friction-coefficient errors μₐᵥₑₐᵣᵣ is equal to or less than a friction coefficient threshold μₜₕ.

In a case where the calculated averaged-friction-coefficient error μₐᵥₑₐᵣᵣ is equal to or less than the friction coefficient threshold μₜₕ, the calculation determiner 14 determines that the calculated friction coefficient μ_{c} corresponding to the averaged-friction-coefficient error μₐᵥₑₐᵣᵣ determined to be equal to or less than the friction coefficient threshold μₜₕ is normal. On the other hand, in a case where the calculated averaged-friction-coefficient error μₐᵥₑₐᵣᵣ is not equal to or less than the friction coefficient threshold μₜₕ, the calculation determiner 14 determines that the calculated friction coefficient μ_{c} corresponding to the averaged-friction-coefficient error μₐᵥₑₐᵣᵣ determined to be not equal to or less than the friction coefficient threshold μₜₕ is abnormal.

The friction coefficient threshold μₜₕ is an evaluated maximum value of an allowable variation amount of a calculated friction coefficient μ_{c} in a case where a plurality of calculated friction coefficients μ_{c} is calculated on the basis of the information detected from the detection unit S in a predetermined control cycle. The friction coefficient threshold μₜₕ is preliminarily set in the calculation determiner 14, and can be obtained by, for example, a preliminarily performed experiment.

In step S83, the calculation determiner 14 erases, among the calculated friction coefficients μ_{c} associated with the calculated slip ratios s_{c} not determined to be abnormal, information of a calculated friction coefficient μ_{c} whose averaged-friction-coefficient error μₐᵥₑₐᵣᵣ has been determined to be not equal to or less than the friction coefficient threshold μₜₕ, and erases information of the calculated slip ratio s_{c} associated with the calculated friction coefficient μ_{c} in question.

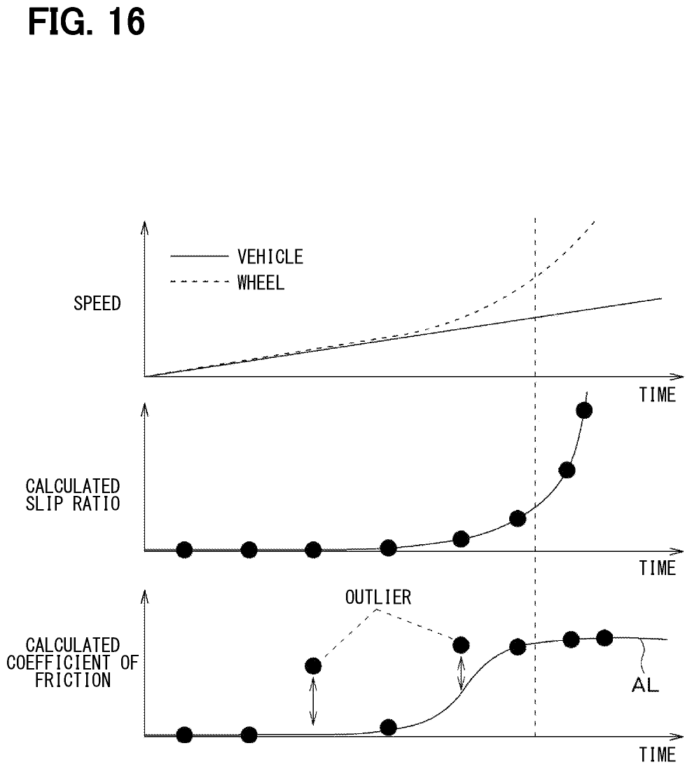

As a result, for example, in a case where the temporal variations in the calculated slip ratio s_{c} and the calculated friction coefficient μ_{c} are illustrated as in FIG. 16, the calculated friction coefficient μ_{c} that deviates very much from the moving averaged AL of the calculated friction coefficients μ_{c} can be determined as an outlier. Then, the information of the calculated friction coefficient μ_{c} that is the outlier can be erased, and the information of the calculated slip ratio s_{c} associated with the calculated friction coefficient μ_{c} in question can be erased.

In a not illustrated case where a calculated slip ratio s_{c} that deviates very much from the moving averaged of the calculated slip ratios s_{c} exists, the calculated slip ratio s_{c} can be determined as an outlier. Then, the information of the calculated slip ratio s_{c} that is the outlier can be erased, and the information of the calculated friction coefficient μ_{c} associated with the calculated slip ratio s_{c} can be erased.

In step S87, the calculation determiner 14 transmits, to the maximum-friction-estimating unit 20, the information of the calculated slip ratios s_{c} and the information of the calculated friction coefficients μ_{c} that have not been erased in step S83. Specifically, the calculation determiner 14 transmits, to the model calculator 21, pieces of information of the calculated slip ratios s_{c}, among the ten calculated slip ratios s_{c} acquired from the calculation memory 13, except a piece of information of the calculated slip ratio s_{c} erased in step S83. In addition, the calculation determiner 14 transmits, to the error calculator 22, pieces of information of the calculated friction coefficients μ_{c}, among the ten calculated friction coefficients μ_{c} acquired from the calculation memory 13, except a piece of information of the calculated friction coefficient μ_{c} erased in step S83. Then, on the basis of the input information of the calculated slip ratios s_{c} and the input information of the calculated friction coefficients μ_{c}, the maximum-friction-estimating unit 20 calculates an estimated maximum friction value μₚ by executing the processing illustrated in FIGS. 7 to 10.

As described above, the computing unit 10 of the present embodiment includes the calculation memory 13 that stores ten pieces of information of calculated slip ratios s_{c} and ten pieces of information of calculated friction coefficients μ_{c}. The computing unit 10 also includes the calculation determiner 14 that determines whether each of the calculated slip ratios s_{c} and each of the calculated friction coefficients μ_{c} stored in the calculation memory 13 is normal.

A parameter-estimating unit 23 estimates the values of the parameters of the tire brush model expression on the basis of the calculated slip ratios s_{c} and the calculated friction coefficients μ_{c} determined to be normal by the calculation determiner 14.

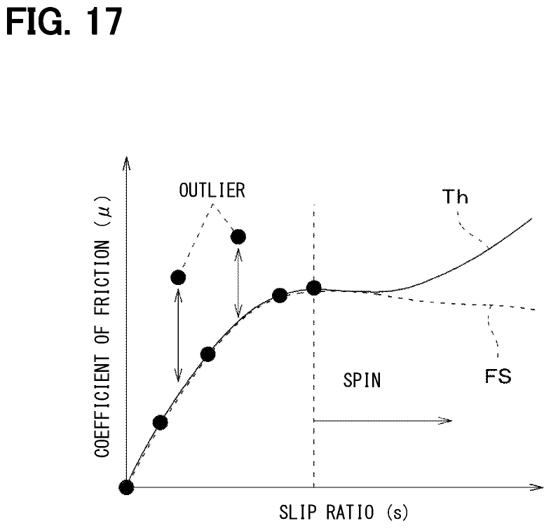

Consequently, in a case where a calculated slip ratio s_{c} and a calculated friction coefficient μ_{c} are abnormal due to noise caused by vibration of the vehicle or the like, the calculation determiner 14 can determine that the calculated slip ratio s_{c} and the calculated friction coefficient μ_{c} are abnormal. Then, the calculation determiner 14 transmits, to the maximum-friction-estimating unit 20, only information of normal calculated slip ratios s_{c} and information of normal calculated friction coefficients μ_{c}. Therefore, as illustrated in FIG. 17, when a theoretical characteristic Th is obtained, the theoretical characteristic Th that does not include an outlier can be obtained. Therefore, when an estimated maximum friction value μₚ is calculated on the basis of the theoretical characteristic Th, an estimated maximum friction value μₚ can be accurately calculated.

According to the above embodiment, the following effects can be obtained.

(1) In the above embodiment, on the basis of the difference between an averaged-slip-ratio error sₐᵥₑₐᵣᵣ and the slip ratio threshold sₜₕ, the calculation determiner 14 determines whether the calculated slip ratio s_{c} stored in the calculation memory 13 is normal. In addition, on the basis of the difference between an averaged-friction-coefficient error μₐᵥₑₐᵣᵣ and the friction coefficient threshold μₜₕ, the calculation determiner 14 determines whether the calculated friction coefficient μ_{c} stored in the calculation memory 13 is normal.

Consequently, it is possible to easily determine whether a calculated slip ratio s_{c} and a calculated friction coefficient μ_{c} are normal.

### Modification of Second Embodiment

In the second embodiment described above, on the basis of the difference between an averaged-slip-ratio error sₐᵥₑₐᵣᵣ and the slip ratio threshold sₜₕ, the calculation determiner 14 determines whether the calculated slip ratio s_{c} is normal. In addition, on the basis of the difference between an averaged-friction-coefficient error μₐᵥₑₐᵣᵣ and the friction coefficient threshold μₜₕ, the calculation determiner 14 determines whether the calculated friction coefficient μ_{c} is normal. However, a method for determining whether a calculated slip ratio s_{c} is normal and a method for determining whether a calculated friction coefficient μ_{c} is normal are not limited to this method.

For example, the calculation determiner 14 may use a moving average to determine whether a calculated slip ratio s_{c} and a calculated friction coefficient μ_{c} are normal.

### Third Embodiment

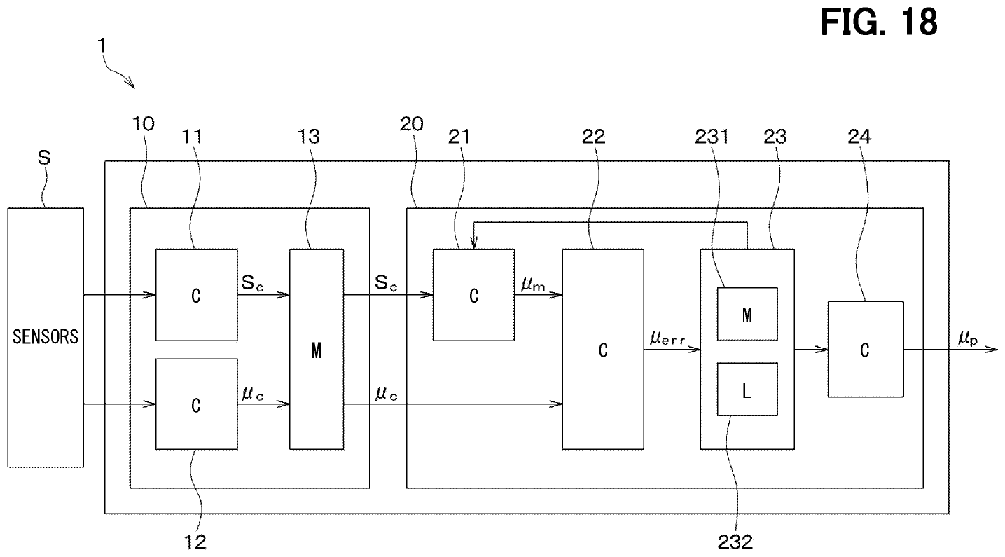

Next, a third embodiment will be described with reference to FIGS. 18 to 23. The present embodiment is different from the second embodiment in that a computing unit 10 does not include the calculation determiner 14. Further, the present embodiment is different from the second embodiment in part of control processing executed by the computing unit 10. Except the differences, the present embodiment is similar to the second embodiment. Therefore, in the present embodiment, the portions different from those of the second embodiment will be mainly described, and description of the portions similar to those of the second embodiment may be omitted.

As illustrated in FIG. 18, the computing unit 10 does not include the calculation determiner 14. Similarly to the second embodiment, a calculation memory 13 stores, in a first address M1 to a 10th address M10, ten pieces of information of calculated slip ratio s_{c} and ten pieces of information of calculated friction coefficients μ_{c} that have been calculated in the same control cycles and are associated with each other in the calculation memory 13, respectively.

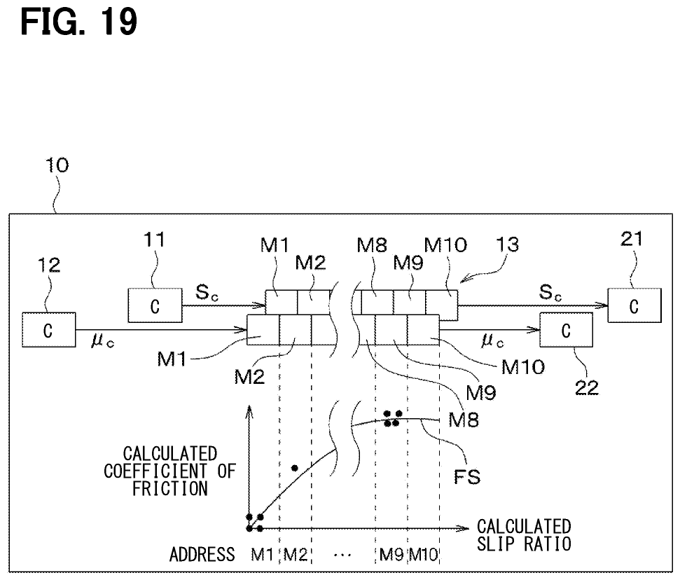

However, for the calculation memory 13 of the present embodiment, as illustrated in FIG. 19, the information of a calculated slip ratio s_{c} stored in each of the first address M1 to the 10th address M10 is determined on the basis of the value of the calculated slip ratio s_{c}. That is, the information of a calculated slip ratio s_{c} stored in each of the first address M1 to the 10th address M10 of the calculation memory 13 is determined depending on the value of the stored calculated slip ratio s_{c}.

The value of a calculated slip ratio s_{c} stored in each of the first address M1 to the 10th address M10 has a predetermined range. In the present embodiment, the first address M1 to the 10th address M10 are set to store pieces of information of calculated slip ratios s_{c} whose values are in the range of 0.0 to 0.1. Each of the first address M1 to the 10th address M10 is set to store Information of a calculated slip ratio s_{c} in every region obtained by equally dividing, by ten, a range of the value of a calculated slip ratio s_{c} from 0.0 to 0.1. In other words, the information of a calculated slip ratio s_{c} stored in the first address M1 to the 10th address M10 is set such that among values of a calculated slip ratio s_{c} in the range from 0.0 to 0.1, any of the ten regions which have the same range is stored.

For example, in a case where the value of a calculated slip ratio s_{c} input from a slip calculator 11 is zero or more and less than 0.01, the information of the calculated slip ratio s_{c} is stored in the first address M1. In a case where the value of a calculated slip ratio s_{c} input from the slip calculator 11 is 0.01 or more and less than 0.02, the information of the calculated slip ratio s_{c} is stored in the second address M2. In a case where the value of a calculated slip ratio s_{c} input from the slip calculator 11 is 0.08 or more and less than 0.09, the information of the calculated slip ratio s_{c} is stored in the ninth address M9. In a case where the value of a calculated slip ratio s_{c} input from the slip calculator 11 is 0.09 or more and 0.1 or less, the information of the calculated slip ratio s_{c} is stored in the 10th address M10. Although details of the values of calculated slip ratios s_{c} input into the third address M3 to the eighth address M8 are not described, pieces of information of calculated slip ratios s_{c} having a range of 0.01 each are stored similarly as in the first address M1 and the like.

As described above, each of the first address M1 to the 10th address M10 is preliminarily determined such that the values of the stored calculated slip ratios s_{c} are different from each other. The information of calculated slip ratios s_{c} stored in the first address M1 to the 10th address M10 is not limited to calculated slip ratios s_{c} in the range from 0.0 to 0.1. For example, the information of calculated slip ratios s_{c} stored in the first address M1 to the 10th address M10 may be in a range narrower than the range from 0.0 to 0.1 (for example, a range from 0.0 to 0.08). Alternatively, the information of calculated slip ratios s_{c} stored in the first address M1 to the 10th address M10 may be in a range wider than the range from 0.0 to 0.1 (for example, a range from 0.0 to 0.15).

The ranges of the values of calculated slip ratios s_{c} stored in the first address M1 to the 10th address M10 may be set to be different from each other. For example, the range of the value of a calculated slip ratio s_{c} stored in each of the first address M1 to the 10th address M10 may be set to be wider in the order from the first address M1 to the 10th address M10. Alternatively, the range of the value of a calculated slip ratio s_{c} stored in each of the first address M1 to the 10th address M10 may be set to be narrower in the order from the first address M1 to the 10th address M10.

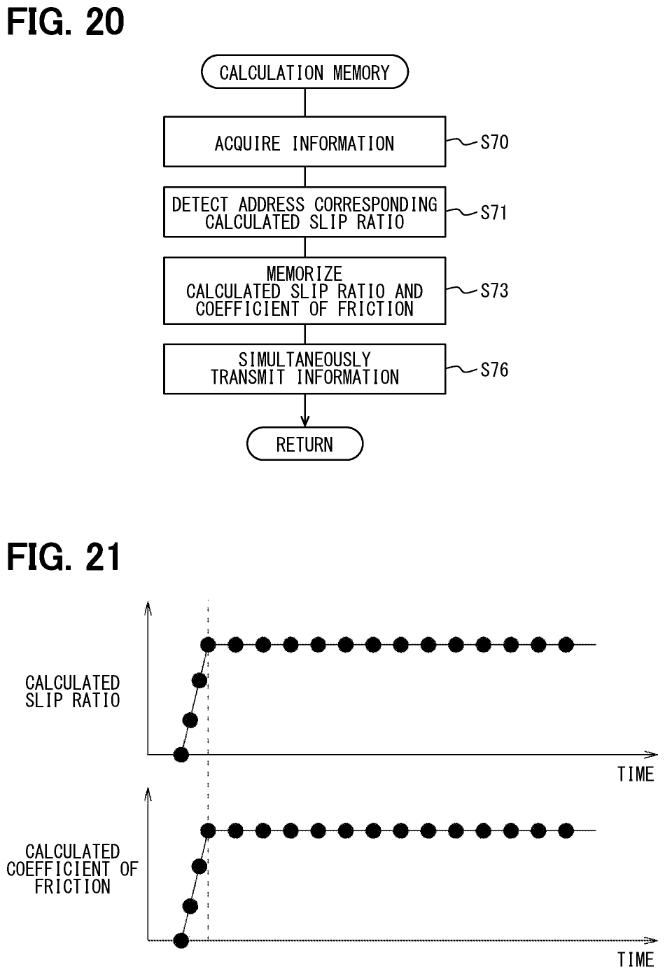

Next, control processing executed by the calculation memory 13 will be described with reference to FIG. 20. The calculation memory 13 repeatedly executes the processing illustrated in FIG. 20 each time both information of a calculated slip ratio s_{c} is input from the slip calculator 11 and information of a calculated friction coefficient μ_{c} is input from a friction calculator 12.

First, in step S70, the calculation memory 13 acquires information of a calculated slip ratio s_{c} from the slip calculator 11, and acquires information of a calculated friction coefficient μ_{c} from the friction calculator 12. Then, in step S71, on the basis of the value of the calculated slip ratio s_{c} acquired from the slip calculator 11, the calculation memory 13 detects, among the first address M1 to the 10th address M10, an address corresponding to the acquired calculated slip ratio s_{c}.

For example, in a case where the value of a calculated slip ratio s_{c} input from the slip calculator 11 is 0.005, the calculation memory 13 detects a corresponding address as the first address M1. In a case where the value of a calculated slip ratio s_{c} input from the slip calculator 11 is 0.085, the calculation memory 13 detects a corresponding address as the ninth address M9.

Then, in step S73, the calculation memory 13 stores, in the corresponding address, the information of the calculated slip ratio s_{c} acquired from the slip calculator 11. In addition, the calculation memory 13 stores the information of a calculated friction coefficient μ_{c} calculated in the same control cycle as the calculated slip ratio s_{c} in the same address as the address where the information of the calculated slip ratio s_{c} is stored. As a result, the information of the calculated slip ratio s_{c} and the information of the calculated friction coefficient μ_{c} that have been calculated in the same control cycle are stored and associated with each other in the same address.

When the calculation memory 13 stores the information of the calculated slip ratio s_{c} in the corresponding address in step S73, in a case where information of a calculated slip ratio s_{c} has been already stored in the address to be stored, the calculation memory 13 erases the stored old information of the calculated slip ratio s_{c} to store the information of the calculated slip ratio s_{c}. That is, in a case where the information of a calculated slip ratio s_{c} acquired in a past control cycle has been already stored in an address to be stored, the calculation memory 13 updates the information of the calculated slip ratio s_{c} to a newly acquired information of a calculated slip ratio s_{c}.

Each time information of a calculated slip ratio s_{c} is input from the slip calculator 11, the calculation memory 13 repeats the processing illustrated in FIG. 20 to store the information of the calculated slip ratio s_{c} and information of the calculated friction coefficient μ_{c} in a corresponding address among the first address M1 to the 10th address M10. As a result, the information of the calculated slip ratio s_{c} and the information of the calculated friction coefficient μ_{c} are stored in every preliminarily determined region of calculated slip ratios s_{c}, in the calculation memory 13.

In step S76, the calculation memory 13 transmits, to a maximum-friction-estimating unit 20, the stored information of the calculated slip ratios s_{c} and the stored information of the calculated friction coefficients μ_{c}. Specifically, the calculation memory 13 transmits, to a model calculator 21, the information of the calculated slip ratio s_{c} stored in each of the first address M1 to the 10th address M10. In addition, the calculation memory 13 transmits, to an error calculator 22, the information of the calculated friction coefficient μ_{c} stored in each of the first address M1 to the 10th address M10. Then, on the basis of the input information of the calculated slip ratios s_{c} and the input information of the calculated friction coefficients μ_{c}, the maximum-friction-estimating unit 20 calculates an estimated maximum friction value μₚ by executing the processing illustrated in FIGS. 7 to 10.

In some cases, the control processing illustrated in FIG. 20 are not executed sufficient times, such as a case immediately after the start of driving of the vehicle, and thus information of a calculated slip ratio s_{c} and information of a calculated friction coefficient μ_{c} are not stored in all the first address M1 to the 10th address M10. Even in such a case, on the basis of the information of the addresses in which information of calculated slip ratios s_{c} and information of calculated friction coefficients μ_{c} are stored, the maximum-friction-estimating unit 20 may calculate an estimated maximum friction value μₚ by executing the processing illustrated in FIGS. 7 to 10.

In a case where information of a calculated slip ratio s_{c} and information of a calculated friction coefficient μ_{c} stored in each of the first address M1 to the 10th address M10 are not updated for a predetermined period, the calculation memory 13 may erase the information of the calculated slip ratios s_{c} and the information of the calculated friction coefficients μ_{c}. For example, in a case where even after a predetermined time elapses after information of a calculated slip ratio s_{c} and information of a calculated friction coefficient μ_{c} are stored in the first address M1, the information has not been updated, the information of the calculated slip ratio s_{c} and the information of the calculated friction coefficient μ_{c} stored in the first address M1 may be erased after the predetermined time elapses. Alternatively, in a case where information of a calculated slip ratio s_{c} and information of a calculated friction coefficient μ_{c} have not been updated in the first address M1, the information of the calculated slip ratio s_{c} and the information of the calculated friction coefficient μ_{c} stored in the first address M1 may be erased after the control processing is performed for a predetermined number of control cycles.

As described above, the information of the calculated slip ratios s_{c} and the information of the calculated friction coefficient μ_{c} are erased, so that in a case where the state of an actual road surface and the state of a past road surface are different, it is possible to avoid an estimated maximum friction value μₚ from being calculated on the basis of the past information.

As described above, the computing unit 10 of the present embodiment includes the calculation memory 13 that stores ten pieces of information of calculated slip ratios s_{c} and ten pieces of information of calculated friction coefficients μ_{c}.

The calculation memory 13 includes the first address M1 to the 10th address M10 corresponding to the magnitude of a calculated slip ratio s_{c}. The calculation memory 13 stores information of a calculated slip ratio s_{c} and information of a calculated friction coefficient μ_{c} in an address preliminarily determined on the basis of the magnitude of the calculated slip ratio s_{c}, among the first address M1 to the 10th address M10.

Consequently, the calculation memory 13 can store information of a calculated slip ratio s_{c} and information of a calculated friction coefficient μ_{c} in every preliminarily determined region of calculated slip ratios s_{c}. Therefore, when a theoretical characteristic Th is obtained, the theoretical characteristic Th can be obtained on the basis of the information of the calculated slip ratio s_{c} and the information of the calculated friction coefficient μ_{c} of each region. Therefore, the theoretical characteristic Th can be easily brought closer to the friction-slip characteristic FS.

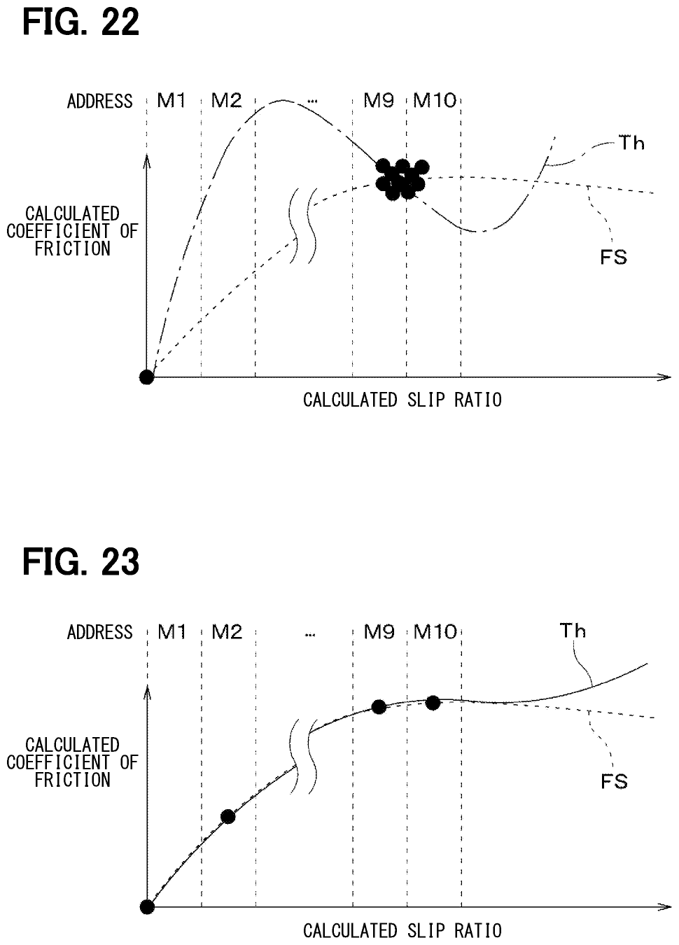

A method for obtaining a theoretical characteristic Th in a case where pieces of information of calculated slip ratios s_{c} having relatively close values and pieces of information of calculated friction coefficients μ_{c} having relatively close values are repeatedly input into the calculation memory 13, as illustrated in FIG. 21, will be considered. In such a case, if pieces of information of calculated slip ratios s_{c} and pieces of information of calculated friction coefficients μ_{c} are stored in the first address M1 to the 10th address M10 in the order of the input, there is a possibility that the theoretical characteristic Th deviates from the friction-slip characteristic FS, such as the theoretical characteristic Th indicated by a dot-dash line of FIG. 22.

The reason is that the theoretical characteristic Th is obtained in a state where the values of the plurality of calculated slip ratios s_{c} are locally detected in one region, and the values of calculated slip ratios s_{c} in the other regions are not detected. In such a case, when the maximum-friction-estimating unit 20 estimates the parameters of the tire brush model expression, the cubic function passing through the approximate values of the values of the local calculated slip ratios s_{c} includes candidates from which an estimated maximum friction value μₚ cannot be accurately calculated. Then, the theoretical characteristic Th may deviate from the friction-slip characteristic FS, such as the theoretical characteristic Th indicated by the dot-dash line of FIG. 21.

On the other hand, according to the present embodiment, the calculation memory 13 stores information of a calculated slip ratio s_{c} and information of a calculated friction coefficient μ_{c} in every preliminarily determined region of calculated slip ratios s_{c}. In addition, in a case where in a state where a piece of information of a calculated slip ratio s_{c} and a piece of information of a calculated friction coefficient μ_{c} are stored in a predetermined region, a piece of information of a new calculated slip ratio s_{c} and a piece of information of a new calculated friction coefficient μ_{c} are input, these pieces of information are updated. In addition, in regions where the piece of information of the calculated slip ratio s_{c} and the piece of information of the calculated friction coefficient μ_{c} are not input, previously input pieces of information of calculated slip ratios s_{c} and previously input pieces of information of calculated friction coefficients μ_{c} are maintained.

Therefore, even in a case where pieces of information of calculated slip ratios s_{c} having relatively close values and pieces of information of calculated friction coefficients μ_{c} having relatively close values are repeatedly input into the calculation memory 13, it is possible to avoid the values of the plurality of calculated slip ratios s_{c} from being locally detected in one region, as illustrated in FIG. 23. In addition, a state where the values of calculated slip ratios s_{c} of the other regions have not been input is avoided.

Therefore, when the maximum-friction-estimating unit 20 estimates the parameters of the tire brush model expression, it is possible to suppress the inclusion of candidates from which an estimated maximum friction value μₚ cannot be accurately calculated. Then, the theoretical characteristic Th can be easily brought closer to the friction-slip characteristic FS.

### Fourth Embodiment

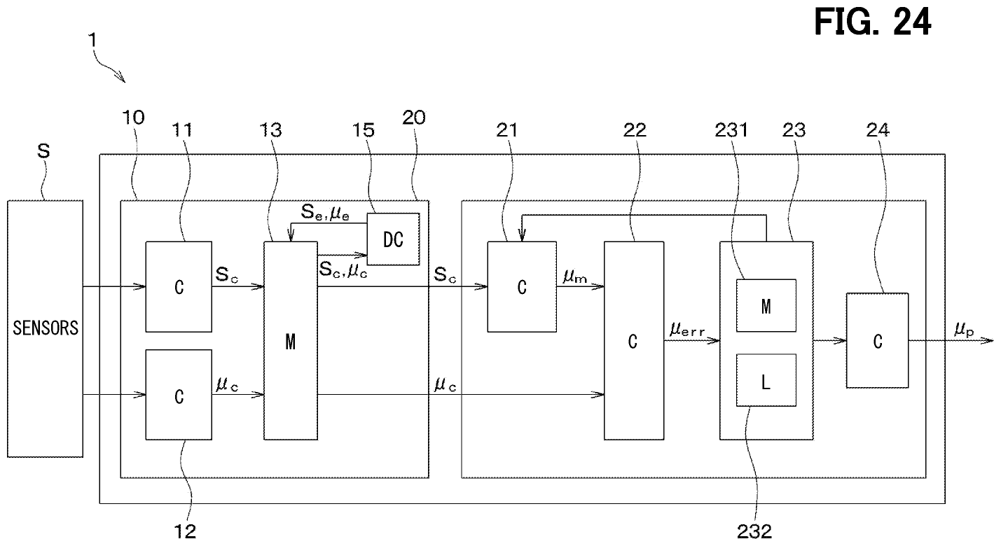

Next, a fourth embodiment will be described with reference to FIGS. 24 to 30. The present embodiment is different from the third embodiment in that a computing unit 10 includes a data-complementing unit 15. Further, the present embodiment is different from the third embodiment in part of control processing executed by the computing unit 10. Except the differences, the present embodiment is similar to the third embodiment. Therefore, in the present embodiment, the portions different from those of the third embodiment will be mainly described, and description of the portions similar to those of the third embodiment may be omitted.

As illustrated in FIG. 24, the computing unit 10 of the present embodiment includes the data-complementing unit 15. The data-complementing unit 15 calculates estimated values of a slip ratio and a friction coefficient to be stored in an address where information of a calculated slip ratio s_{c} and information of a calculated friction coefficient μ_{c} are not stored, among a first address M1 to a 10th address M10 of a calculation memory 13.

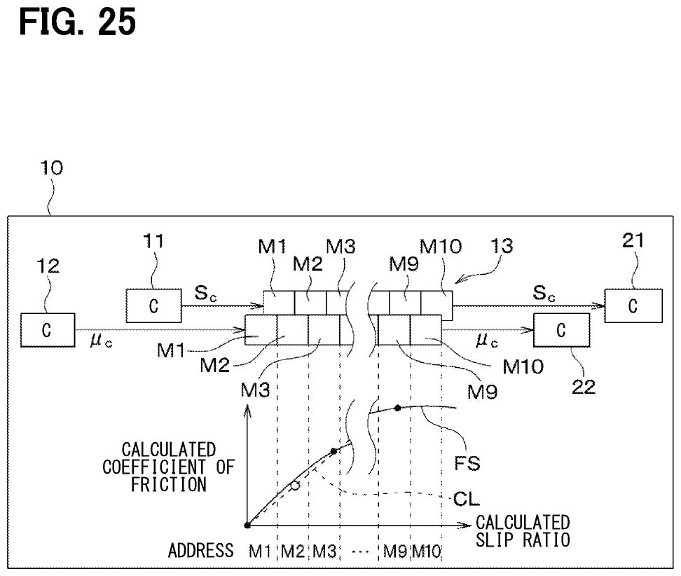

For example, as illustrated in FIG. 25, it is assumed that information of a calculated slip ratio s_{c} and information of a calculated friction coefficient μ_{c} are not stored in the second address M2 among the first address M1 to the 10th address M10 of the calculation memory 13. Further, it is assumed that information of a calculated slip ratio s_{c} and information of a calculated friction coefficient μ_{c} are stored in the addresses except the second address M2, among the first address M1 to the 10th address M10 of the calculation memory 13. In such a case, the data-complementing unit 15 stores, in the second address M2, information of a calculated slip ratio s_{c} and information of a calculated friction coefficient μ_{c} that have been estimated on the basis of the information of the calculated slip ratios s_{c} and the information of the calculated friction coefficients μ_{c} stored in the addresses except the second address M2.

In FIG. 25, pieces of information of calculated friction coefficients μ_{c} stored in the calculation memory 13 are indicated by black circles, and a piece of information of a calculated friction coefficient μ_{c} not stored in the calculation memory 13 is indicated by a white circle.

Hereinafter, an address where information of a calculated slip ratio s_{c} and information of a calculated friction coefficient μ_{c} are stored is referred to as an information-registered address, and an address where information of a calculated slip ratio s_{c} and information of a calculated friction coefficient μ_{c} are not stored is referred to as an information-unregistered address. An estimated value of a slip ratio to be stored in an information-unregistered address is also referred to as an estimated slip ratio sₑ, and an estimated value of a friction coefficient to be stored in an information-unregistered address is also referred to as an estimated friction coefficient μₑ.

The data-complementing unit 15 of the present embodiment uses an approximate curve to obtain an estimated slip ratio sₑ and an estimated friction coefficient μₑ of an information-unregistered address. Specifically, the data-complementing unit 15 may use linear approximation to obtain an estimated slip ratio sₑ and an estimated friction coefficient μₑ of an information-unregistered address. For example, a method for obtaining an estimated slip ratio sₑ and an estimated friction coefficient μₑ in a case where the first address M1 and the third address M3 are information-registered addresses and the second address M2 is an information-unregistered address will be described.

As illustrated in FIG. 25, a virtual line passing through the value of a calculated slip ratio s_{c} stored in each of the first address M1 and the third address M3 adjacent to the second address M2, which is an information-unregistered address, is a virtual line CL. The data-complementing unit 15 calculates, as an estimated slip ratio sₑ, a value positioned on the virtual line CL, among the values of slip ratios of 0.01 or more and less than 0.02 included in the second address M2. In addition, the data-complementing unit 15 calculates, as an estimated friction coefficient μₑ, the value of a friction coefficient corresponding to the estimated slip ratio sₑ thus obtained. Consequently, the data-complementing unit 15 can calculate an estimated slip ratio sₑ and an estimated friction coefficient μₑ to be stored in an information-unregistered address on the basis of calculated slip ratios s_{c} and calculated friction coefficients μ_{c} stored in information-registered addresses adjacent to the information-unregistered address.

A method using which the data-complementing unit 15 calculates an estimated slip ratio sₑ and an estimated friction coefficient μₑ may be a method except linear approximation. For example, the data-complementing unit 15 may use logarithmic approximation to obtain an estimated slip ratio sₑ and an estimated friction coefficient μₑ. Alternatively, the data-complementing unit 15 may use a moving average to obtain an estimated slip ratio sₑ and an estimated friction coefficient μₑ.

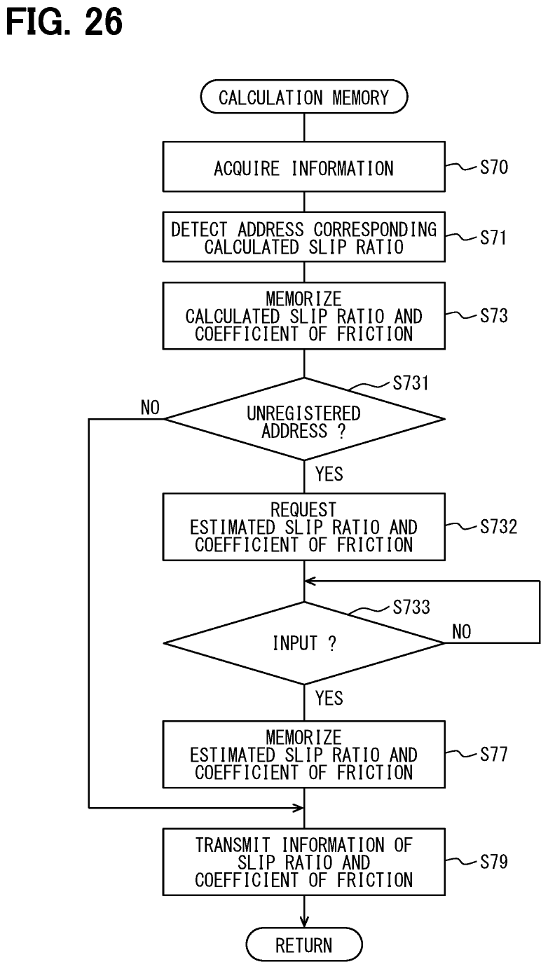

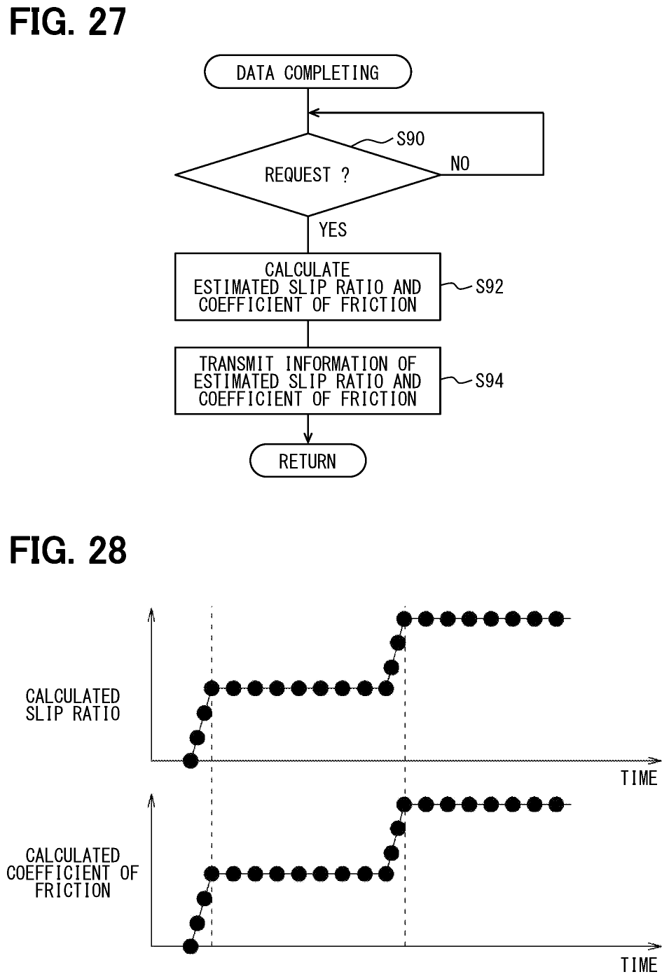

Next, control processing executed by each of the calculation memory 13 and the data-complementing unit 15 will be described with reference to FIGS. 26 and 27. The calculation memory 13 repeatedly executes the processing illustrated in FIG. 26 each time both information of a calculated slip ratio s_{c} is input from a slip calculator 11 and information of a calculated friction coefficient μ_{c} is input from a friction calculator 12. The processing of steps S70, S71, and S73 illustrated in FIG. 26 is similar to the processing of each step of the third embodiment described with reference to FIG. 20, and thus the description is omitted.

After in step S73, the calculation memory 13 stores information of a calculated slip ratio s_{c} and information of a calculated friction coefficient μ_{c} associated with each other in a corresponding address, in step S731, the calculation memory 13 determines whether the first address M1 to the 10th address M10 include an information-unregistered address. In a case where it is not determined that the first address M1 to the 10th address M10 include an information-unregistered address, the processing of steps S732 and S733 is skipped.

On the other hand, in a case where it is determined that the first address M1 to the 10th address M10 include an information-unregistered address, in step S732, the calculation memory 13 transmits, to the data-complementing unit 15, a signal for requesting information of an estimated slip ratio sₑ and information of an estimated friction coefficient μₑ. Further, the calculation memory 13 transmits, to the data-complementing unit 15, information of calculated slip ratios s_{c} and information of calculated friction coefficients μ_{c} stored in information-registered addresses, and information of whether each of the first address M1 to the 10th address M10 is an information-registered address or an information-unregistered address.

In addition, as illustrated in FIG. 27, in step S90, the data-complementing unit 15 determines whether a signal transmitted from the calculation memory 13 for requesting information of an estimated slip ratio sₑ and information of an estimated friction coefficient μₑ has been received. In step S90, the data-complementing unit 15 waits until a signal transmitted from the calculation memory 13 for requesting information of an estimated slip ratio sₑ and information of an estimated friction coefficient μₑ is received.

If the request signal is received, in step S92, the data-complementing unit 15 uses an approximate curve to obtain an estimated slip ratio sₑ and an estimated friction coefficient μₑ to be stored in the information-unregistered address. Specifically, the data-complementing unit 15 uses linear approximation to obtain an estimated slip ratio sₑ and an estimated friction coefficient μₑ on the basis of the information of the calculated slip ratios s_{c} and the information of the calculated friction coefficients μ_{c} stored in the information-registered addresses. In a case where among the first address M1 to the 10th address M10, a plurality of addresses are information-unregistered addresses, the data-complementing unit 15 obtains an estimated slip ratio sₑ and an estimated friction coefficient μₑ to be stored in each of the plurality of information-unregistered addresses.

Then, in step S94, the data-complementing unit 15 transmits, to the calculation memory 13, information of the estimated slip ratio sₑ and information of the estimated friction coefficient μₑ that have been calculated.

Returning to FIG. 26, in step S733, the calculation memory 13 determines whether information of the estimated slip ratio sₑ and information of the estimated friction coefficient μₑ transmitted from the data-complementing unit 15 have been received. In step S733, the calculation memory 13 waits until information of an estimated slip ratio sₑ and information of an estimated friction coefficient μₑ transmitted from the data-complementing unit 15 have been received.

In a case where in step S733, it is determined that information of the estimated slip ratio sₑ and information of the estimated friction coefficient μₑ transmitted from the data-complementing unit 15 have been received, in step S77, the calculation memory 13 stores the information of the estimated slip ratio sₑ in a corresponding information-unregistered address. The calculation memory 13 also stores the information of the estimated friction coefficient μₑ in the corresponding information-unregistered address. As a result, in each of the first address M1 to the 10th address M10, either of information of a calculated slip ratio s_{c} and information of an estimated slip ratio sₑ is stored, and either of information of a calculated friction coefficient μ_{c} and information of an estimated friction coefficient μₑ is stored. Then, the calculation memory 13 proceeds to the processing of step S79.

In step S79, the calculation memory 13 transmits, to a maximum-friction-estimating unit 20, the slip ratio information and the friction coefficient information stored in each of the first address M1 to the 10th address M10. In a case where in step S731, it is determined that the first address M1 to the 10th address M10 include an information-unregistered address, the slip ratio information includes information of an estimated slip ratio sₑ estimated by the data-complementing unit 15 in addition to information of calculated slip ratios s_{c} calculated by the slip calculator 11. Further, in a case where in step S731, it is determined that the first address M1 to the 10th address M10 include an information-unregistered address, the friction coefficient information includes information of an estimated friction coefficient μₑ estimated by the data-complementing unit 15 in addition to information of calculated friction coefficients μ_{c} calculated by the friction calculator 12.

Then, the maximum-friction-estimating unit 20 calculates an estimated maximum friction value μₚ by executing the processing illustrated in FIGS. 7 to 10 on the basis of input information of each of the calculated slip ratios s_{c}, the estimated slip ratio sₑ, the calculated friction coefficients μ_{c}, and the estimated friction coefficient μₑ.

As described above, in the control device 1 of the present embodiment, the computing unit 10 includes the data-complementing unit 15 that allows storage of information of an estimated slip ratio sₑ and information of an estimated friction coefficient μₑ in an information-unregistered address among the first address M1 to the 10th address M10. The data-complementing unit 15 estimates an estimated slip ratio sₑ and an estimated friction coefficient μₑ on the basis of information of calculated slip ratios s_{c} and information of calculated friction coefficients μ_{c} stored in information-registered addresses.

Consequently, even in a case where an information-unregistered address exists among any of the first address M1 to the 10th address M10, the computing unit 10 can obtain an estimated slip ratio sₑ and an estimated friction coefficient μₑ corresponding to the information-unregistered address. Therefore, when a theoretical characteristic Th is obtained, the theoretical characteristic Th can be obtained on the basis of information of each of calculated slip ratios s_{c}, an estimated slip ratio sₑ, calculated friction coefficients μ_{c}, and an estimated friction coefficient μₑ. Therefore, the theoretical characteristic Th can be easily brought closer to the friction-slip characteristic FS.

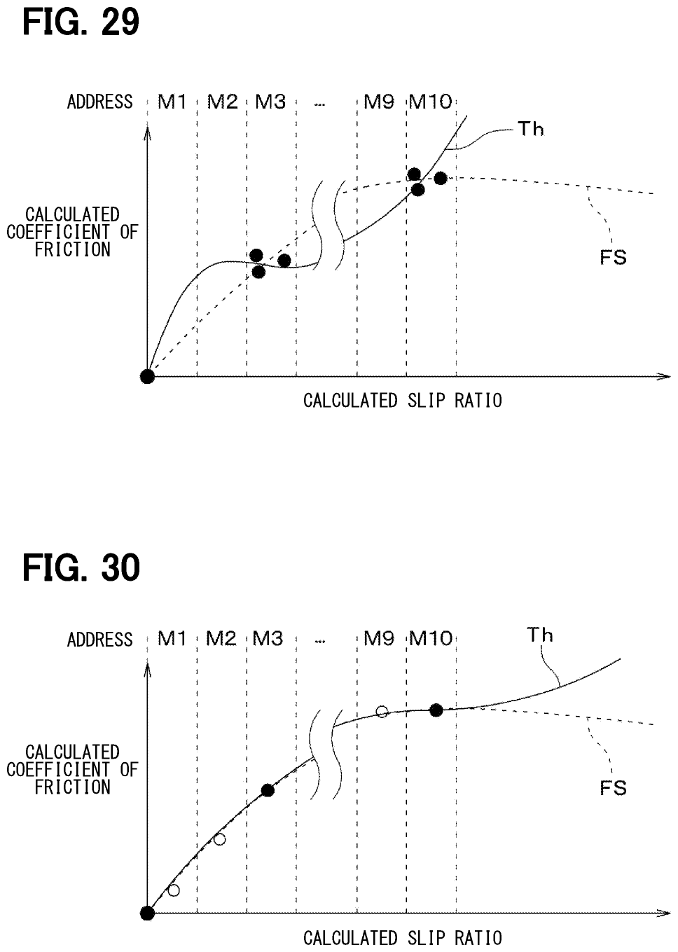

A method for obtaining a theoretical characteristic Th in a case where a calculated slip ratio s_{c} and a calculated friction coefficient μ_{c} rise stepwise, as illustrated in FIG. 28, will be considered. In such a case, in the calculation memory 13, information-registered addresses and information-unregistered addresses exist among the first address M1 to the 10th address M10. Then, in a case where a theoretical characteristic Th is obtained on the basis of only information of calculated slip ratios s_{c} and information of calculated friction coefficients μ_{c} stored in the information-registered addresses, there is a possibility that the theoretical characteristic Th deviates from the friction-slip characteristic FS, such as a theoretical characteristic Th indicated by a solid line of FIG. 29.

The reason is that the theoretical characteristic Th is obtained in a state where among the first address M1 to the 10th address M10, slip ratio information and friction coefficient information are stored in a plurality of addresses, and slip ratio information and friction coefficient information are not stored in the other addresses. In such a case, when the maximum-friction-estimating unit 20 estimates the parameters of the tire brush model expression, the graph of the cubic function passing through the approximate values of the values of the local calculated slip ratios s_{c} includes candidates from which an estimated maximum friction value μₚ cannot be accurately calculated. Then, the theoretical characteristic Th may deviate from the friction-slip characteristic FS, such as the theoretical characteristic Th indicated by the solid line of FIG. 29.

On the other hand, according to the present embodiment, estimated slip ratios sₑ and estimated friction coefficient μₑ corresponding to information-unregistered addresses can be obtained on the basis of information of calculated slip ratios s_{c} and information of calculated friction coefficients μ_{c} stored in information-registered addresses. Therefore, in each of the first address M1 to the 10th address M10, either of information of a calculated slip ratio s_{c} and information of an estimated slip ratio sₑ can be stored, and either of information of a calculated friction coefficient μ_{c} and information of an estimated friction coefficient μₑ can be stored.

Therefore, even in a case where the values of a calculated slip ratio s_{c} and a calculated friction coefficient μ_{c} rising stepwise are detected, it is possible to avoid a state where pieces of slip ratio information and pieces of friction coefficient information are not stored, as illustrated in FIG. 30. Then, when the maximum-friction-estimating unit 20 estimates the parameters of the tire brush model expression, it is possible to avoid the inclusion of candidates for the parameters to be a graph of a cubic function passing only the approximate values of the values of the calculated slip ratios s_{c} where the theoretical characteristic Th concentrates.

Therefore, when the maximum-friction-estimating unit 20 estimates the parameters of the tire brush model expression, it is possible to suppress the inclusion of candidates from which an estimated maximum friction value μₚ cannot be accurately calculated. Then, the theoretical characteristic Th can be easily brought closer to the friction-slip characteristic FS.

### Other Embodiments

Although the representative embodiments of the present disclosure have been described above, the present disclosure is not limited to the above-described embodiments, and can be variously modified as follows, for example:

In the embodiments, the friction-coefficient-computing device is used for the vehicle control system that controls the traveling of the electric car and is included in the ECU that controls the rotation speed of the motor for driving the vehicle, and the like, but the example is not limitative.

For example, the friction-coefficient-computing device may be used in a brake system that controls braking of the vehicle, and may be included in an ECU that controls the brake. Alternatively, the friction-coefficient-computing device may be used alone, and provided in the vehicle. In this case, the friction-coefficient-computing device includes a microcomputer including a CPU and memories, such as a ROM and a RAM, and a peripheral circuit of the microcomputer.

In the above-described embodiment, the parameter-restricting unit 232 obtains the values of the parameters so as to allow the inclination of the inflection point of the tire brush model expression to be zero, but the example is not limitative. While the inclination of the inflection point of the tire brush model expression can be brought closer to zero, the values of the parameters restricted by the parameter-restricting unit 232 may be values that do not allow the inclination of the inflection point of the tire brush model expression to be zero.

In the above-described embodiment, the region where the slip ratio is 0.1 or less is set as a minute region, and the tire brush model expression in the minute region is shown by Formula 6 and the like, but the example is not limitative. As long as the value of the slip ratio is sufficiently less than the slip ratio at which wheelspin of the tire starts, the tire brush model expression shown by Formula 6 and the like can be adopted even in a region where the slip ratio includes a value more than 0.1.

Needless to say, the elements constituting the above embodiments are not necessarily essential, except for cases, such as a case where it is clearly indicated that the elements are particularly essential, and a case where it is considered that the elements are obviously essential in principle.

In the above-described embodiment, in a case where numerical values, such as the numbers, numerical values, amounts, and ranges, of constituent elements of the embodiments are mentioned, the specific numbers are not limitative, except for cases, such as a case where it is clearly indicated that the numerical values are particularly essential, and a case where the numerical values are obviously limited to the specific numbers in principle.

In the above-described embodiments, when the shapes, positional relationships, and the like of the constituent elements and the like are mentioned, the shapes, positional relationships, and the like are not limitative, except for cases, such as a case where it is clearly indicated, and a case where the specific shapes, positional relationships, and the like are limitative in principle.

What is claimed is:

1. A friction-coefficient-computing device that estimates an estimated maximum friction value μₚ, which is an estimated maximum value of a friction coefficient between a tire and a road surface, using a tire brush model that simulates a physical phenomenon between the tire and the road surface, and on a basis of a detection signal transmitted from a detection unit that detects information relating to the tire when a vehicle travels on the road surface, the friction-coefficient-computing device comprising:
a computing unit that calculates a slip ratio between the tire and the road surface, and calculates a friction coefficient between the tire and the road surface on a basis of the detection signal; and
a maximum-friction-estimating unit that calculates the estimated maximum friction value using the slip ratio and the friction coefficient calculated by the computing unit, and a tire brush model expression, which is a computation expression indicating a relationship between a slip ratio and a friction coefficient in the tire brush model, and is for calculating an estimated friction coefficient between the tire and the road surface in a case where the slip ratio between the tire and the road surface is in a minute region where the slip ratio is less than a slip ratio at which wheelspin of the tire starts, wherein
assuming that the slip ratio calculated by the computing unit is a calculated slip ratio s_{c}, and the friction coefficient calculated by the computing unit is a calculated friction coefficient μ_{c},
the tire brush model expression is a function relating to the slip ratio of the tire brush model, and includes a plurality of parameters that varies an inclination of the tire brush model expression,
the maximum-friction-estimating unit includes:
a model calculator that substitutes the calculated slip ratio into the tire brush model expression to calculate a tire model friction μₘ, which is a friction coefficient of the tire brush model; and
a parameter-estimating unit that estimates values of the parameters so as to make smaller a difference between the calculated friction coefficient and the tire model friction, and
the parameter-estimating unit includes a parameter-restricting unit that eliminates values of the parameters that allow the tire brush model expression to be a linear function and a quadratic function, and obtains values of the parameters that allow an inclination of an inflection point of the tire brush model expression to approach zero.

2. The friction-coefficient-computing device according to claim 1, wherein
the tire brush model expression is represented by Formula of:
μₘ=(H*3s−HK*3s²+HK²*s³)/F_{z}
the parameters are H, HK, and HK² in Formula,
the tire model friction represents μₘ in Formula,
the slip ratio between the tire and the road surface represents s in Formula,
a normal force generated on the tire represents F_{z} in Formula, and
the parameter-restricting unit restricts values of the parameters to satisfy a Formula of HK²=(HK)²/H in terms of the parameters.

3. The friction-coefficient-computing device according to claim 1, wherein
the parameter-estimating unit includes a parameter-storing unit that acquires information relating to each of the calculated slip ratio and the calculated friction coefficient calculated by the computing unit, and stores a predetermined number of pieces of the acquired information, and estimates values of the parameters using the pieces of information stored in the parameter-storing unit and relating to the plurality of calculated slip ratios and the plurality of calculated friction coefficients, respectively, and
each time the parameter-storing unit acquires a piece or pieces of information relating to each of the calculated slip ratio and the calculated friction coefficient from the computing unit, the parameter-storing unit updates a piece or pieces of information of the stored pieces of information relating to the plurality of calculated slip ratios and the plurality of calculated friction coefficients, respectively, and a number of the updated piece or pieces of information is a number of the acquired piece or pieces of information.

4. The friction-coefficient-computing device according to claim 1, wherein
the computing unit includes a calculation memory that stores a plurality of pieces of information of the calculated slip ratios and a plurality of pieces of information of the calculated friction coefficients, and a calculation determiner that determines whether at least one of the calculated slip ratios and the calculated friction coefficients stored in the calculation memory is normal, and
the parameter-estimating unit estimates values of the parameters on a basis of the calculated slip ratios and the calculated friction coefficients determined to be normal by the calculation determiner.

5. The friction-coefficient-computing device according to claim 4, wherein
on a basis of a difference between an average value of the plurality of calculated slip ratios stored in the calculation memory and a preliminarily determined slip ratio threshold, the calculation determiner determines whether the calculated slip ratios stored in the calculation memory are normal, and on a basis of a difference between an average value of the plurality of calculated friction coefficients stored in the calculation memory and a preliminarily determined friction coefficient threshold, the calculation determiner determines whether the calculated friction coefficients stored in the calculation memory are normal.

6. The friction-coefficient-computing device according to claim 1, wherein
the computing unit includes a calculation memory that stores a plurality of pieces of information of the calculated slip ratios and a plurality of pieces of information of the calculated friction coefficients, and
the calculation memory includes a plurality of addresses corresponding to magnitudes of the calculated slip ratios, and stores the pieces of information of the calculated slip ratios and the pieces of information of the calculated friction coefficients in addresses preliminarily determined on a basis of the magnitudes of the calculated slip ratios, among the plurality of addresses.

7. The friction-coefficient-computing device according to claim 6, wherein
the computing unit includes a data-complementing unit that stores information of an estimated slip ratio and information of an estimated friction coefficient in an information-unregistered address in which the information of the calculated slip ratio and the information of the calculated friction coefficient are not stored, among the plurality of addresses, and
on a basis of the information of the calculated slip ratios and the information of the calculated friction coefficients stored in the calculation memory, the data-complementing unit estimates a slip ratio and a friction coefficient to be stored in the information-unregistered address.
